(19) United States
(12) Patent Application Publication
(10) Pub. No.: US 2015/0171823 A1
(43) Pub. Date: Jun. 18, 2015

(54) CMOS FABRICATION OF A THIN-FILM BULK ACOUSTIC RESONATOR

(71) Applicant: The Silanna Group Pty Ltd, Brisbane, Queensland (AU)

(72) Inventor: Andrew J. Brawley, Brisbane (AU)

(21) Appl. No.: 14/414,880

(22) PCT Filed: Jul. 15, 2013
(86) PCT No.: PCT/AU2013/000785

§ 371 Date: Jan. 14, 2015

Related U.S. Application Data
(60) Provisional application No. 61/671,919, filed on Jul. 16, 2012.

(51) Int. Cl. H03H 9/205; H01L 41/29; H01L 41/187; H01L 21/84; H01L 27/12; H01L 27/20; H01L 21/762

(52) U.S. Cl. CPC H03H 9/205; H01L 27/20; H01L 41/29; H01L 21/76254; H01L 21/84; H01L 27/1203; H01L 41/187

(57) ABSTRACT

A process of forming a thin-film bulk acoustic resonator (FBAR) device (130, 914) on a silicon-on-thin film aluminum-nitride on silicon (SOFTANOS) substrate (110) using a CMOS fabrication process is provided. The SOFTANOS substrate, which is an example of a high thermal conductivity silicon-on-insulator (SOI) substrate, comprises an aluminum nitride (AlN) layer (114) and a silicon layer (118). The AlN layer has low electrical conductivity, high thermal conductivity, and good piezoelectric properties. A CMOS device (140, 910) is formed in the silicon layer, and the FBAR device is formed in the AlN layer.

### FIELD

The present invention relates generally to acoustic resonators and semiconductor manufacturing processes, and more particularly to a process of forming an integrated circuit structure including a thin-film bulk acoustic resonator (FBAR) device and a complementary metal oxide semiconductor (CMOS) device using a CMOS fabrication process.

### BACKGROUND

A thin-film bulk acoustic resonator (FBAR or TFBAR) is a device that is based on the transduction of acoustic waves. An FBAR is one type of bulk acoustic wave (BAW) device. BAW and FBAR devices are often used as electronic filters. An FBAR comprises a piezoelectric material sandwiched between two electrodes that are acoustically isolated from the surrounding medium. FBAR devices using piezoelectric films with thicknesses ranging from several microns down to tenths of a micron resonate in the frequency range of roughly 100 MHz to 10 GHz.

A common application of FBAR devices is for radio frequency (RF) filters for use in cell phones and other wireless applications. In an FBAR device, the transduction from electrical energy to mechanical energy is accomplished by the use of the piezoelectric materials. Because FBAR devices use piezoelectric materials, they cannot be integrated into conventional complementary metal oxide semiconductor (CMOS)-based semiconductor fabrication processes, which do not use piezoelectric materials.

### BRIEF DESCRIPTION OF THE DRAWINGS

The features and advantages of the present invention will be more clearly understood from the following description taken in conjunction with the accompanying drawings, wherein:

FIG. 1 is a cross-sectional view of a generalized example of an integrated circuit (IC) structure that comprises both an FBAR device and a CMOS device that are formed using a silicon-on-thin film aluminum-nitride on silicon (SOFTANOS) substrate;

FIG. 2 is a cross-sectional view of a SOFTANOS substrate having piezoelectric properties;

FIG. 3 is a flow diagram of an example method of forming the SOFTANOS substrate shown in FIG. 2;

FIG. 4 illustrates a cross sectional view of a bulk silicon substrate including a hydrogen implant layer;

FIG. 5 illustrates a cross sectional view of the substrate of FIG. 4 further including an AlN layer;

FIG. 6A illustrates the substrate of FIG. 5, further including a removable handle substrate;

FIG. 6B illustrates the substrate of FIG. 6A, wherein the removable handle substrate is weakly bonded to the AlN layer;

FIG. 7 illustrates the substrate of FIG. 6B, with a portion of the bulk silicon layer partially removed;

FIG. 8 illustrates the substrate of FIG. 7, with the portion of the bulk silicon layer completely removed;

FIG. 9A shows a plan view of an example of an IC structure formed using a CMOS fabrication process that utilizes a SOFTANOS substrate;

FIG. 9B shows a cross-sectional view of the example of the IC structure of FIG. 9A;

FIG. 10A illustrates a plan view of the SOFTANOS substrate of FIG. 2, further including a silicon dioxide layer, a silicon nitride layer and a photoresist layer;

FIG. 10B illustrates a cross-sectional view of the substrate of FIG. 10A;

FIG. 11A illustrates a plan view of the substrate of FIG. 10A, wherein a mask pattern has been formed in the photoresist layer;

FIG. 11B illustrates a cross-sectional view of the substrate of FIG. 11A;

FIG. 12A illustrates a plan view of the substrate of FIG. 11A, wherein portions of the silicon nitride layer and the silicon dioxide layer are etched away through the mask pattern;

FIG. 12B illustrates a cross-sectional view of the substrate of FIG. 12A;

FIG. 13A illustrates a plan view of the substrate of FIG. 12A, wherein the silicon dioxide layer and the silicon nitride layer are removed;

FIG. 13B illustrates a cross-sectional view of the substrate of FIG. 13A;

FIG. 14A illustrates a plan view of the substrate of FIG. 13A, wherein a mask pattern is formed on the substrate;

FIG. 14B illustrates a cross-sectional view of the substrate of FIG. 14A;

FIG. 15A illustrates a plan view of the substrate of FIG. 14A, wherein a silicon dioxide layer is removed;

FIG. 15B illustrates a cross-sectional view of the substrate of FIG. 15A;

FIG. 16A illustrates a plan view of the substrate of FIG. 15A, further including a blanket polysilicon layer;

FIG. 16B illustrates a cross-sectional view of the substrate of FIG. 16A;

FIG. 17A illustrates a plan view of the substrate of FIG. 16A, further including a mask pattern;

FIG. 17B illustrates a cross-sectional view of the substrate of FIG. 17A;

FIG. 18A illustrates a plan view of the substrate of FIG. 17A, wherein the mask pattern is removed and a silicide blanket layer is formed;

FIG. 18B illustrates a cross-sectional view of the substrate of FIG. 18A;

FIG. 19A illustrates a plan view of the substrate of FIG. 18A, comprising a further mask pattern;

FIG. 19B illustrates a cross-sectional view of the substrate of FIG. 19A;

FIG. 20A illustrates a plan view of the substrate of FIG. 19A, wherein layers have been etched according to the further mask pattern;

FIG. 20B illustrates a cross-sectional view of the substrate of FIG. 20A;

FIG. 21A illustrates a plan view of the substrate of FIG. 20A, further comprising a blanket layer of silicon dioxide;

FIG. 21B illustrates a cross-sectional view of the substrate of FIG. 21A;

FIG. 22A illustrates a plan view of the substrate of FIG. 21A, wherein a spacer oxide layer is etched to form an oxide spacer on each side of the gate structure;

FIG. 22B illustrates a cross-sectional view of the substrate of FIG. 22A;

FIG. 23A illustrates a plan view of the substrate of FIG. 22A, further comprising a blanket dielectric layer;

FIG. 23B illustrates a cross-sectional view of the substrate of FIG. 23A;

FIG. 24A illustrates a plan view of the substrate of FIG. 23A, wherein the dielectric layer is etched to provide certain openings;

FIG. 24B illustrates a cross-sectional view of the substrate of FIG. 24A;

FIG. 25A illustrates a plan view of the substrate of FIG. 24A, further comprising a blanket layer of metal;

FIG. 25B illustrates a cross-sectional view of the substrate of FIG. 25A;

FIG. 26A illustrates a plan view of the substrate of FIG. 25A, wherein the blanket layer of metal is etched to define metal contacts;

FIG. 26B illustrates a cross-sectional view of the substrate of FIG. 26A;

FIG. 27A illustrates a plan view of the substrate of FIG. 26A, further comprising a blanket layer of passivation material;

FIG. 27B illustrates a cross-sectional view of the substrate of FIG. 27A;

FIG. 28A illustrates a plan view of the substrate of FIG. 27A, wherein the passivation layer is etched to reestablish openings around the electrodes;

FIG. 28B illustrates a cross-sectional view of the substrate of FIG. 28A;

FIG. 29A illustrates a plan view of the substrate of FIG. 28A, wherein the passivation layer is planarized and a handle substrate is bonded to the passivation layer;

FIG. 29B illustrates a cross-sectional view of the substrate of FIG. 29A;

FIG. 30A illustrates a plan view of the substrate of FIG. 29A, wherein the removable handle substrate has been removed from the AlN layer;

FIG. 30B illustrates a cross-sectional view of the substrate of FIG. 30A;

FIG. 31A illustrates a plan view of the substrate of FIG. 30A, further comprising a vent, and wherein the substrate has been inverted;

FIG. 31B illustrates a cross-sectional view of the substrate of FIG. 31A;

FIG. 32A illustrates a plan view of the substrate of FIG. 31A, further comprising electrodes forming FBAR devices;

FIG. 32B illustrates a cross-sectional view of the substrate of FIG. 32A; and

FIG. 33 is a flow diagram of an example of a method of integrating a CMOS device and an FBAR device using the SOFTANOS substrate.

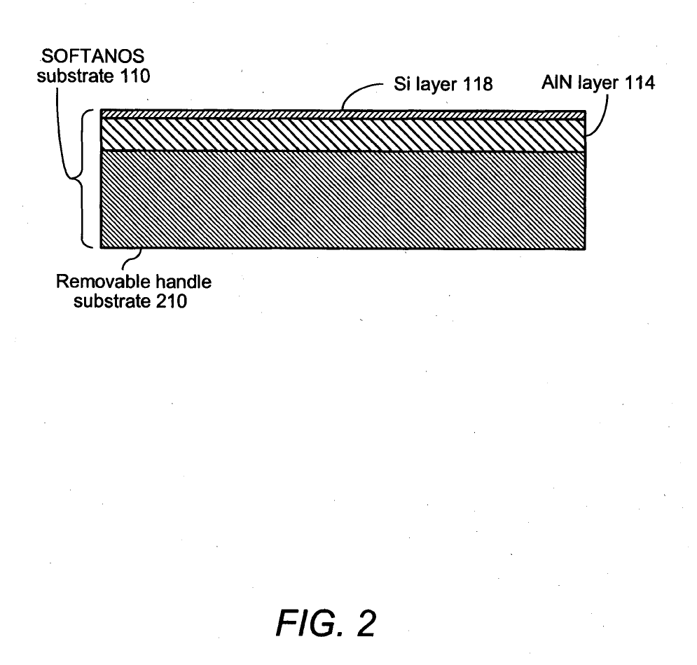

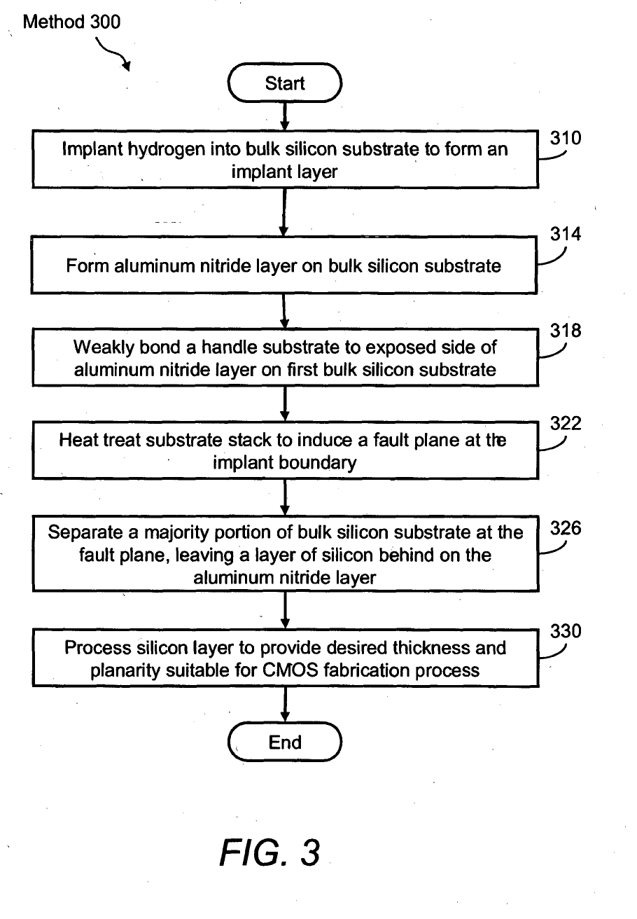

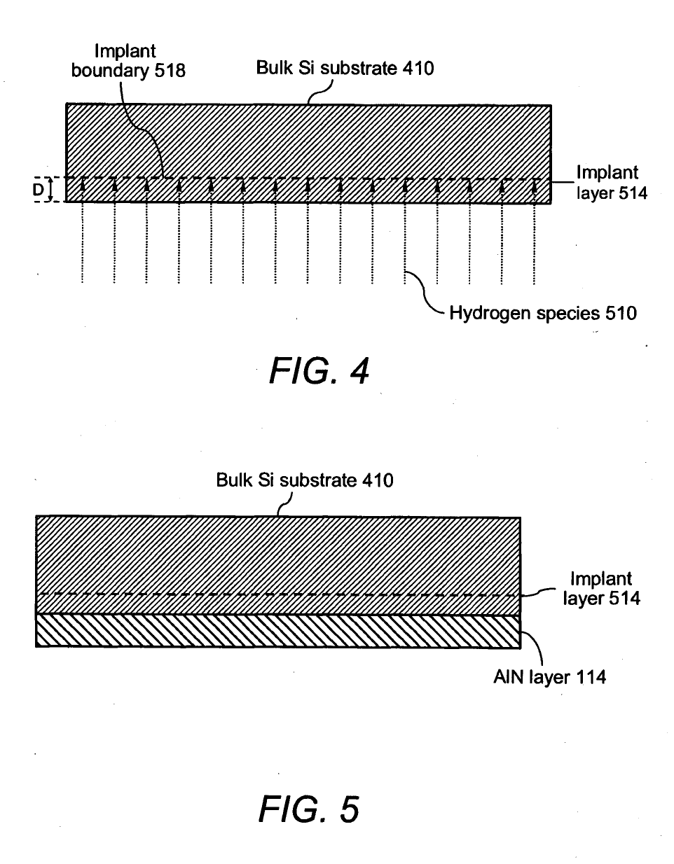

FIG. 4 through FIG. 8 collectively illustrate a process of forming the SOFTANOS substrate of FIG. 2 according to the method of FIG. 3.

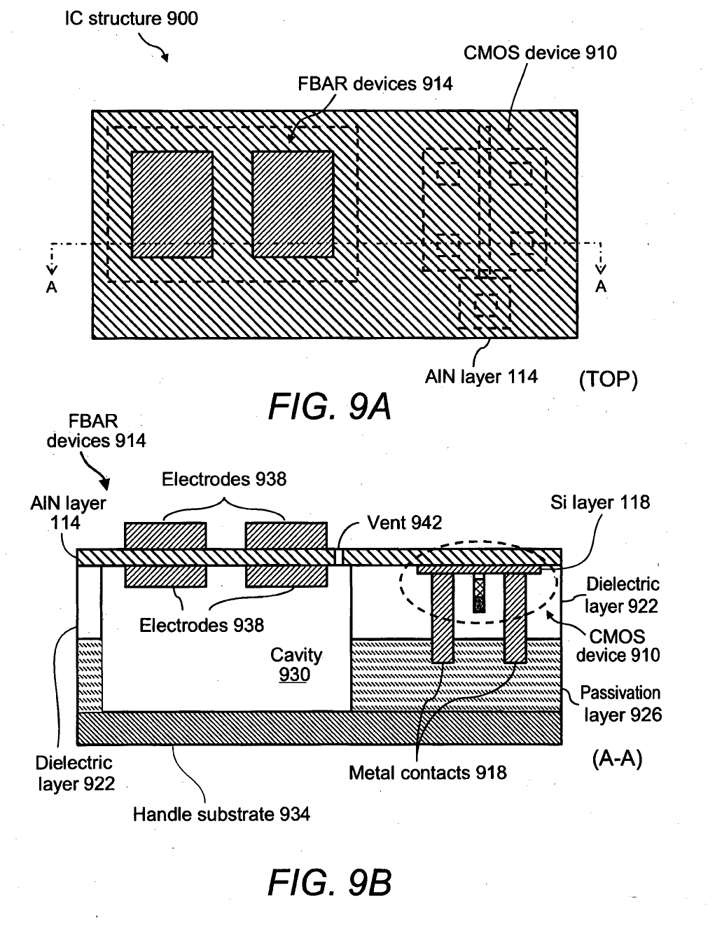

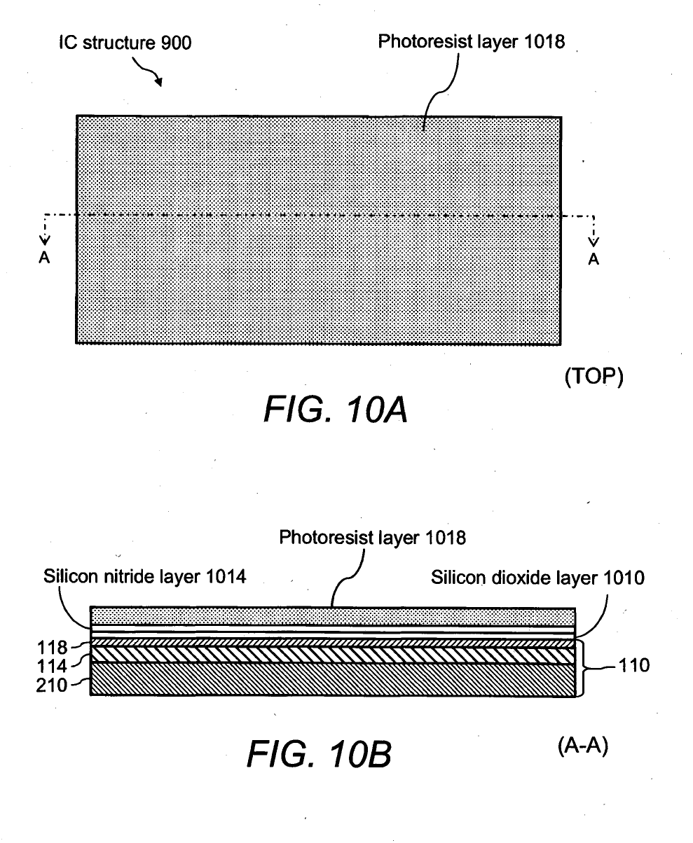

FIG. 10A and FIG. 10B through FIG. 32A and FIG. 32B collectively illustrate an example of a sequence of the CMOS fabrication process steps used to form the IC structure shown in FIGS. 9A and 9B, wherein the starting substrate of the CMOS fabrication process is the SOFTANOS substrate.

### DETAILED DESCRIPTION

A process of forming an integrated circuit (IC) structure including a thin-film bulk acoustic resonator (FBAR) device and a complementary metal oxide semiconductor (CMOS) device using a CMOS fabrication process is provided, wherein the CMOS fabrication process uses a silicon-on-thin film aluminum-nitride on silicon (SOFTANOS) substrate. More specifically, the SOFTANOS substrate comprises a silicon layer atop a thin layer of aluminum nitride on a temporary silicon substrate. The SOFTANOS substrate is bonded to a removable handler substrate that facilitates the handling of the SOFTANOS substrate during the CMOS fabrication process. The aluminum nitride layer has low electrical conductivity (i.e., it is an electrical insulator), high thermal conductivity, and good piezoelectric properties.

Because the aluminum nitride layer of the SOFTANOS substrate has piezoelectric properties, the SOFTANOS substrate is suitable for forming FBAR devices. The use of the SOFTANOS substrate supports the use of a CMOS fabrication process wherein both CMOS devices and FBAR devices are formed using a SOFTANOS substrate. For example, CMOS devices may be formed starting with the silicon layer of the SOFTANOS substrate, while FBAR devices may be formed using the aluminum nitride layer of the same SOFTANOS substrate.

An aspect of the disclosure includes an IC structure that includes the one or more CMOS device formed in the silicon layer and the one or more FBAR devices formed in the aluminum nitride layer of the SOFTANOS substrate.

More particularly, an FBAR device can be formed by (1) removing a portion of the silicon layer of the SOFTANOS substrate to expose the aluminum nitride layer, (2) providing a first electrode on the exposed aluminum nitride layer, (3) removing the handler substrate that is weakly bonded to the aluminum nitride layer of the SOFTANOS substrate to expose the reverse side of the same aluminum nitride layer, and (4) providing a second electrode on the reverse side of the same aluminum nitride layer. Further, the electrodes and piezoelectric material of the FBAR device are maintained in atmosphere so that vibration of the FBAR device is not inhibited, thereby substantially achieving acoustical isolation from the surrounding medium.

FBAR devices are passive devices that can be used in the appropriate application to sink signals that generate heat. However, because of the high heat dissipation that the aluminum nitride layer of the SOFTANOS substrate permits, the SOFTANOS substrate provides greater thermal management capability than do conventional substrates, which have poor thermal conductivity. Therefore, both CMOS devices and FBAR devices may be integrated using the SOFTANOS substrate. This is because the SOFTANOS substrate provides both high thermal conductivity and piezoelectric properties.

Accordingly, a method of integrating CMOS devices and FBAR devices using the SOFTANOS substrate is provided that reduces the complexity and cost of implementing both CMOS technology and FBAR technology as compared with using conventional substrates and methods. Further, the implementation of FBAR devices using a CMOS manufacturing process enables these FBAR devices to be formed with operating frequencies of up to about 30 GHz, which far exceeds that of conventional discrete FBAR devices, whose maximum operating frequency is limited to about 10 GHz.

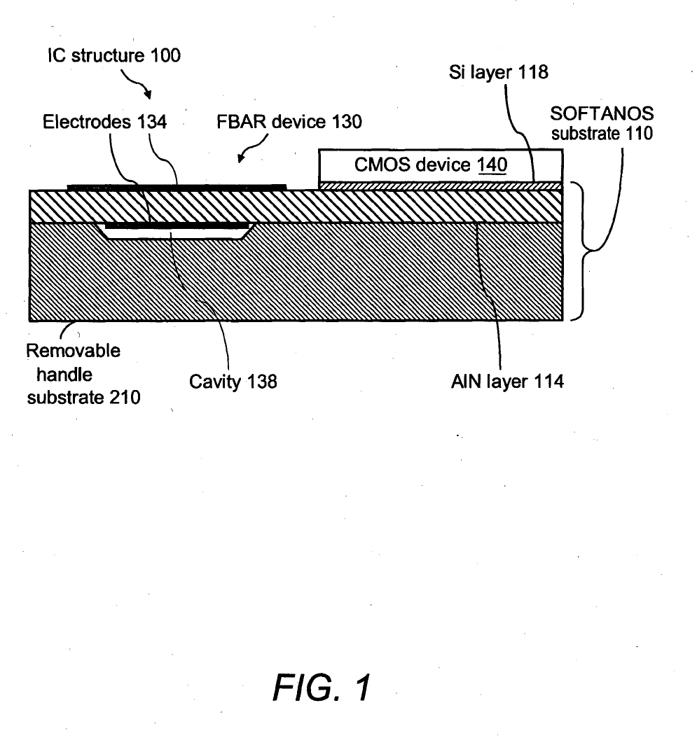

FIG. 1 is a cross-sectional view of a generalized example of an IC structure 100 that comprises both an FBAR device and a CMOS device that are formed using a SOFTANOS substrate 110. The SOFTANOS substrate 110 comprises an aluminum nitride (AlN) layer 114, a silicon (Si) layer 118 and a removable handle substrate 210. The AlN layer 114 has low electrical conductivity, high thermal conductivity, and good piezoelectric properties, which is well-suited for forming FBAR devices. At the same time, the Si layer 118 is well-suited for the starting layer of any CMOS fabrication process. More details of the SOFTANOS substrate 110 are described below with reference to FIG. 2 through FIG. 8.

The removable handle substrate 210 is a bulk substrate that is formed, for example, of silicon, metal, quartz, or other materials depending on the application. An FBAR device 130 and a CMOS device 140 is formed on the SOFTANOS substrate 110 using a CMOS fabrication process. Further, a cavity 138 is provided above the removable handle substrate 210 at the location of the FBAR device 130. The FBAR device 130 is formed by removing a portion of the Si layer 118 of the SOFTANOS substrate 110 to expose a portion of the AlN layer 114. A first electrode 134 is provided on one side (i.e., the exposed side) of the AlN layer 114 and a second electrode 134 on the reverse side of the AlN layer 114 that is in the cavity 138 of the removable handle substrate 210. Because the cavity 138 is provided between the second electrode 134 and the removable handle substrate 210, the electrodes 134 and the portion of the AlN layer 114 forming the FBAR device 130 are maintained in atmosphere and thus the FBAR device 130 is acoustically isolated from the surrounding medium.

Because the FBAR device 130 is fabricated using a CMOS manufacturing process, an example FBAR device 130 can have an operating frequency of up to about 30 GHz. The frequency limit of the CMOS process is determined by the geometry of the transistors. For present conventional 0.25-micron processes, the practical limit of the operating frequency is about 15 GHz. However, using deep sub-micron processes (e.g., 65-nanometer processes) the operating frequency can exceed 60 GHz, which far exceeds that of conventional discrete FBAR devices, whose maximum operating frequency is limited to about 10 GHz.

As will be readily understood by a person skilled in the art, the IC structure 100 can be easily extended to include a plurality of CMOS devices 140 and/or a plurality of FBAR devices 130.

FIG. 2 is a cross-sectional view of an example of the SOFTANOS substrate 110, which has piezoelectric properties. The SOFTANOS substrate 110 comprises the AlN layer 114 and the Si layer 118 mounted atop the removable handle substrate 210. The removable handle substrate 210 is a bulk substrate that is formed, for example, of silicon, metal, quartz, or other materials, depending on the application. For example, the removable handle substrate 210 is weakly bonded to the AlN layer 114 of the SOFTANOS substrate 110. The bond between the removable handle substrate 210 and the AlN layer 114 is intentionally weak so that the removable handle substrate 210 can be removed at a certain point in the CMOS fabrication process.

The thickness of the AlN layer 114 is up to several microns in one example, from about 50 nm to about 1 μm in another example, from about 50 nm to about 250 nm in yet another example, or about 200 nm in yet another example. The AlN layer 114 serves as the piezoelectric material that is needed to form FBAR devices, while the Si layer 118 serves as the starting layer for formation of CMOS circuitry. Therefore, the Si layer 118 is a thin layer of silicon. For example, the thickness of the Si layer 118 is from about 75 nm to about 110 nm, in one example, or about 100 nm in another example. However, the thicknesses of the Si layer 118 and the AlN layer 114 may vary depending on the application.

The removable handle substrate 210 serves as the base substrate and, therefore, is suitably thick to perform this function. The thickness of the removable handle substrate 210 may vary depending on a diameter of the SOFTANOS substrate 110. Namely, the larger the diameter, the thicker the removable handle substrate 210. If the diameter of the SOFTANOS substrate 110 is 150 mm, then the thickness of the removable handle substrate 210 is from about 600 μm to about 700 μm in one example, or about 675 μm in another example.

Again, the bond between the AlN layer 114 and the removable handle substrate 210 is weak, which allows the removable handle substrate 210 of the SOFTANOS substrate 110 to be separated from the AlN layer 114 and removed as needed in the CMOS fabrication process. In particular, it is necessary to remove the removable′ handle substrate 210 in the process of producing FBAR devices using the CMOS fabrication process. In one example, the SOFTANOS substrate 110 is based on the substrate disclosed in International Publication WO/2013/067572, published May 16, 2013, entitled “A semiconductor-on-insulator structure and process for producing same,” which application is incorporated herein by reference. More details of a method of forming the SOFTANOS substrate 110, which includes the weak bond between the AlN layer 114 and the removable handle substrate 210, are now described with reference to FIG. 3 through FIG. 8.

FIG. 3 is a flow diagram of an example method 300 of forming a SOFTANOS substrate, such as the SOFTANOS substrate 110 of FIG. 2. FIG. 4 through FIG. 8 show the process of forming the SOFTANOS substrate 110 according to the method 300 of FIG. 3. In one example, the method 300 is based on the method described with reference to the aforementioned International Publication WO/2013/067572. The method 300 includes the steps below.

At a step 310, hydrogen is implanted into a bulk silicon substrate. For example and referring now to FIG. 4, a bulk Si substrate 410 is ion implanted with a gaseous hydrogen species 510 to form a buried implant layer 514. In one example, about 140 keV H⁺ ions are implanted to an areal density of about 6×10¹⁶ cm². The implant layer 514 has a depth D, which is the depth to which the species are implanted into the bulk Si substrate 410. In one example, the depth D of the implant layer 514 is from about 1 μm to about 1.2 μm. An implant boundary 518 indicates the boundary of the implant layer 514 that is deepest into the bulk Si substrate 410.

At a step 314, an aluminum nitride layer is formed on the bulk silicon substrate after the hydrogen is implanted. For example and referring now to FIG. 5, the AlN layer 114 is formed on the bulk Si substrate 410 after the gaseous hydrogen species 510 is implanted. The AlN layer 114 has a thickness of from about 250 nm to about 1 μm. In general, the thickness of the AlN layer 114 will be selected to provide sufficient thermal conductance to enable semiconductor devices formed using the SOFTANOS substrate 110 to be operated at a desired power as well as at the operating frequency of the FBAR device. Accordingly, the AlN layer 114 in other embodiments may be thicker. Typically, the thickness of the AlN layer 114 does not exceed about 1 μm, but thicknesses of several microns can be required for certain high-power applications. The AlN layer 114 can be grown on the bulk Si substrate 410 by molecular beam epitaxy (MBE), reactive sputtering, metal-organic chemical vapor deposition (MOCVD), or hydride vapor-phase epitaxy (HVPE) using standard methods known to those skilled in the art.

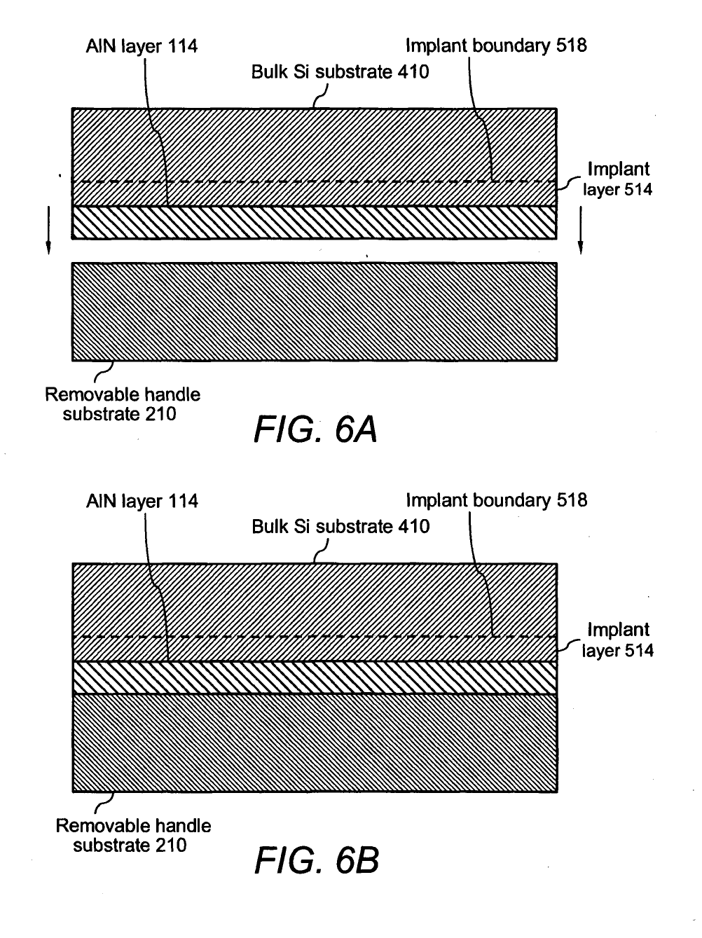

At a step 318, a handle substrate is weakly bonded to an exposed side of the aluminum nitride layer on the bulk silicon substrate. For example and referring now to FIG. 6A and FIG. 6B, the AlN layer 114, which has been grown on the bulk Si substrate 410, is weakly bonded to the removable handle substrate 210. In so doing, a substrate stack is formed.

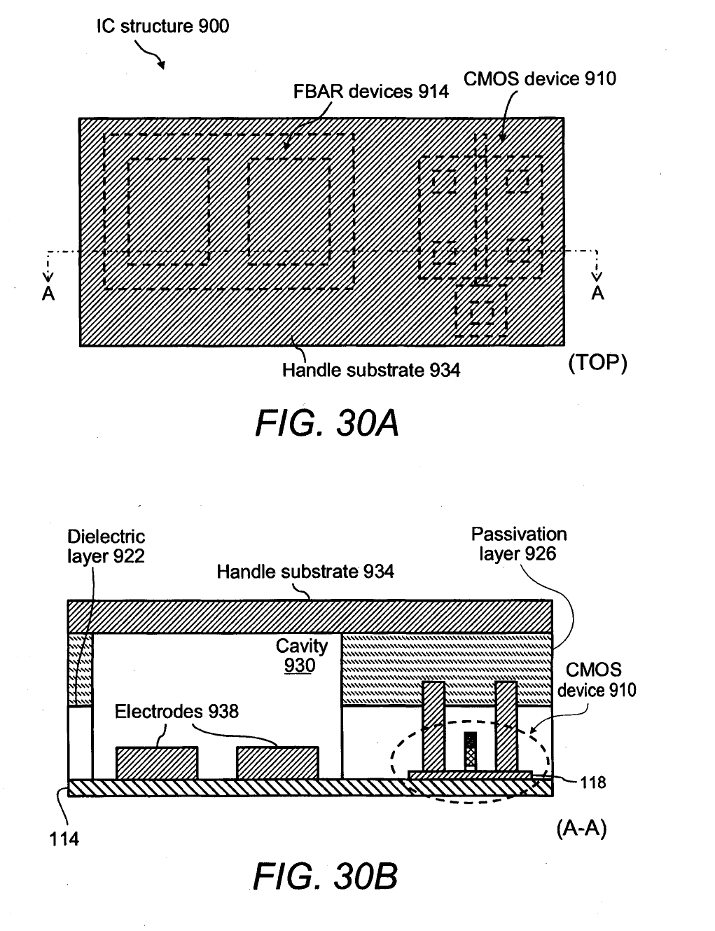

In one example, the removable handle substrate 210 is a standard silicon wafer having a polished surface with a surface roughness of <1 nm, root mean squared (RMS). The bonding between AlN and Si is generally rather poor; however, in the context of the described embodiments, this is desirable because the bonding between the AlN layer 114 and the removable handle substrate 210 is to be reversed when used in a CMOS manufacturing process, an example of which is described later in FIG. 30A and FIG. 30B. In any case, the strength of the bonding is increased by heating the substrate stack at a low temperature for a short period (e.g., about 120° C. for 2 hours) and then raising the temperature for a longer period (e.g., about 300° C. for 10 hours) to further improve the bonding strength. However, it will be apparent to those skilled in the art that other combinations of temperature and time can be readily determined to provide a suitable bond strength that is sufficient to maintain the bonding during processing up until the AlN layer 114 and the removable handle substrate 210 are separated.

At a step 322, the substrate stack is heat treated to induce a fault plane at a boundary between the implanted hydrogen and the bulk silicon substrate, such as the implant boundary 518. For example and referring again to FIGS. 6A and 6B, the substrate stack, which comprises the removable handle substrate 210, the AlN layer 114, and the bulk Si substrate 410, is heat treated at a temperature sufficient to induce a fault plane at the implant boundary 518 so that a majority portion of the bulk Si substrate 410 can be subsequently split away and removed. In one example, the substrate stack is heated to a temperature of about 400° to 600° C. for about 15 minutes.

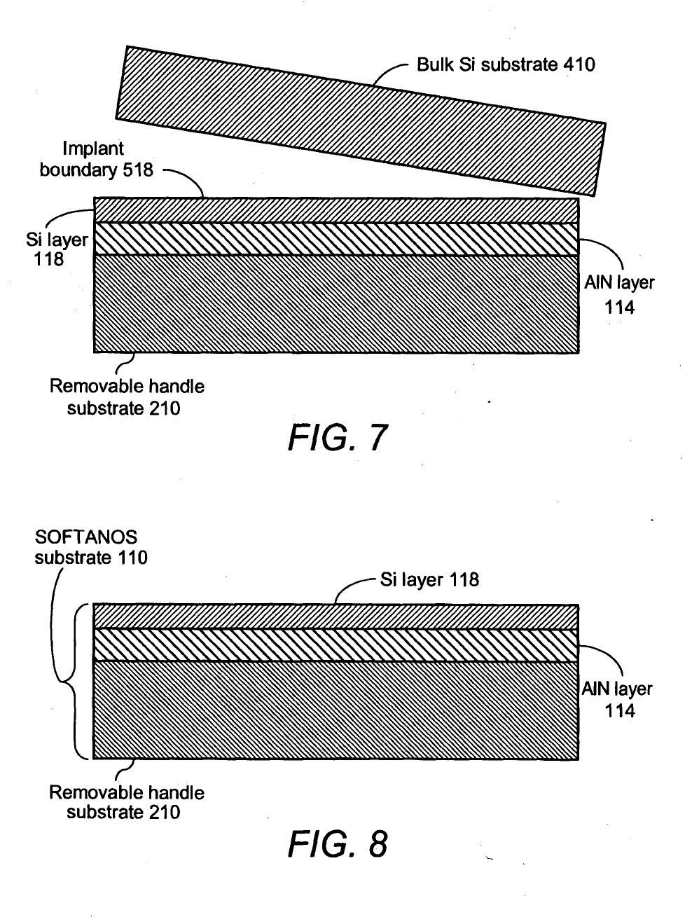

At a step 326, a majority portion of the bulk silicon substrate is separated at the fault plane and removed, leaving a thin layer of silicon behind on the aluminum nitride layer. For example and referring now to FIG. 7, a majority portion of the bulk Si substrate 410 is split at the fault plane that has formed at the implant boundary 518 and removed, leaving behind the Si layer 118 on the AlN layer 114, as shown in FIG. 8. At this point in the process, the Si layer 118 has a rough surface and will require further processing. After the non-bonded portion of the bulk Si substrate 410 (which can be re-used) has been removed, the remaining structure is annealed at a temperature of up to 1,100° C. for about 1 hour to anneal, any residual damage to the Si layer 118 caused by the implanted hydrogen and to remove the hydrogen from the Si layer 118.

At a step 330, the silicon layer is processed to provide a desired thickness and planarity that is suitable for the CMOS fabrication process. As known by those skilled in the art, “ion-cut” processes leave a rough surface on the remaining silicon layer. For example and referring now to FIG. 8, the surface of the Si layer 118 on the AlN layer 114 is subjected to a chemical mechanical polish/planarization (CMP) process to reduce the thickness of the Si layer 118 to, for example, from about 75 nm to about 110 nm, depending on process parameters, thereby forming the SOFTANOS substrate 110 shown in FIG. 2. The SOFTANOS substrate 110 has a smooth, device-quality semiconductor thin film (i.e., the Si layer 118) on the AlN layer 114. The SOFTANOS substrate 110 is now ready for use in any CMOS fabrication process.

FIG. 9A shows a plan view an example of an IC structure 900 formed using a SOFTANOS substrate, such as the SOFTANOS substrate 110 of FIG. 2. FIG. 9B includes a cross-sectional view of the IC structure 900 taken along line A-A of the plan view.

In this example, the IC structure 900 comprises a CMOS device 910 and two FBAR devices 914 that are formed using the SOFTANOS substrate 110; namely, the SOFTANOS substrate 110 is the starting substrate for the CMOS fabrication process. For example, the CMOS device 910 is formed on or in the Si layer 118 of the SOFTANOS substrate 110, while the FBAR devices 914 are formed using the AlN layer 114 of the SOFTANOS substrate 110. The CMOS device 910 includes metal contacts 918, which are supported by a dielectric layer 922 (e.g., a boron phospho-silicate glass (BPSG) interlayer dielectric (ILD) oxide layer) and a passivation layer 926. The portion of the AlN layer 114 that includes the two FBAR devices 914 is exposed to the atmosphere (e.g., air) on both sides. For example, one side of the AlN layer 114 is exposed directly to the atmosphere, while the reverse side of the AlN layer 114 faces a cavity 930, such as an air cavity. The cavity 930 is bounded on four sides by the dielectric layer 922 and the passivation layer 926, while the floor of the cavity 930 is bounded by a handle substrate 934. The handle substrate 934 is a bulk substrate that is formed, for example, of silicon, metal, quartz, or other materials depending on the application.

Each of the two FBAR devices 914 includes a pair of electrodes 938, wherein a first electrode of the pair of electrodes 938 is on one side of the AlN layer 114 and a second electrode of the pair of electrodes 938 is on the reverse side of the AlN layer 114, as shown in FIG. 9A and FIG. 9B. In this way, the pairs of electrodes 938 and the portion of the AlN layer 114 forming the FBAR devices 914 are maintained in the atmosphere and thus the FBAR devices 914 are acoustically isolated from the surrounding medium. Optionally, a vent 942 is provided through the AlN layer 114 to provide an air path to the cavity 930 or alternatively substantially mechanically isolating the AlN layer 114 from its surrounding structure.

Using the method of forming an FBAR device on a low electrical conductivity, high thermal conductivity, and piezoelectric substrate, namely, on the SOFTANOS substrate 110, FBAR devices, such as the FBAR devices 914, can be fabricated that can operate at frequencies up to about 30 GHz using the features of the advanced CMOS process. The operating frequency of an FBAR is primarily determined by the thickness of the AlN layer 114 between the FBAR electrodes 938, the resistance of the electrodes and the quality of the AlN in terms of phase velocity which for example can be 5,000 m/s to 10,000 m/s.

FIG. 10A and FIG. 10B through FIG. 32A and FIG. 32B collectively illustrate an example of a sequence of the CMOS fabrication process steps used to form the IC structure 900 of FIG. 9A and FIG. 9B, wherein the starting substrate of the CMOS fabrication process is the SOFTANOS substrate 110. The steps of the CMOS fabrication process shown in FIG. 10A and FIG. 10B through FIG. 32A and FIG. 32B collectively constitute one example of a CMOS fabrication process that utilizes a SOFTANOS substrate, such as the SOFTANOS substrate 110, as the starting substrate. However, the method is not limited to the sequence of the CMOS fabrication process steps shown in FIG. 10A and FIG. 10B through FIG. 32A and FIG. 32B. Any CMOS fabrication process of any CMOS manufacturer may be used to form any arrangement of FBAR devices and CMOS devices on the SOFTANOS substrate 110. FIG. 10A and FIG. 10B through FIG. 32A and FIG. 32B each include a plan view of a portion of the IC structure 900 and a cross-sectional view of the IC structure 900 taken along line A-A of the corresponding plan view.

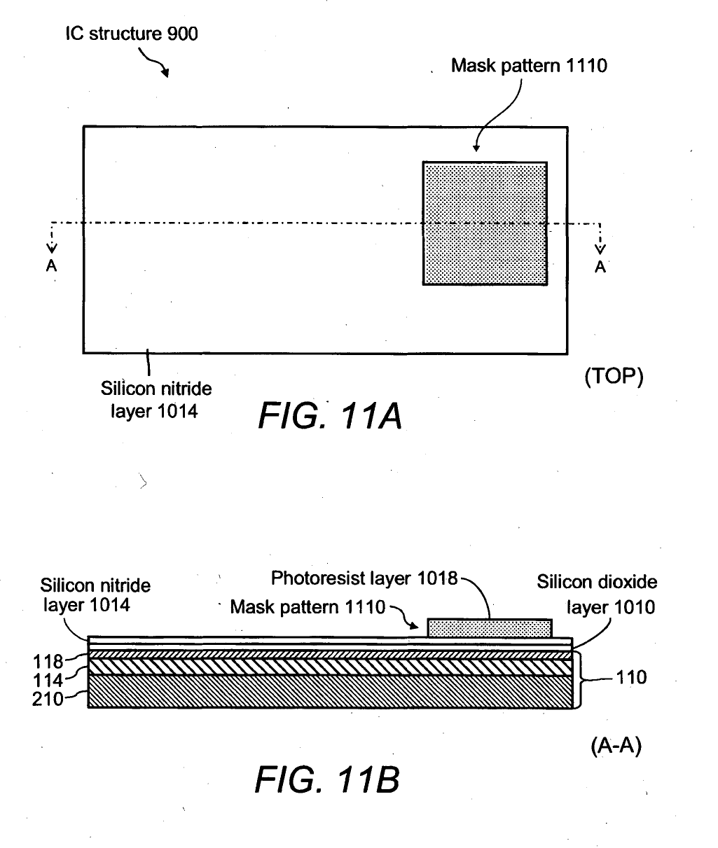

FIG. 10A and FIG. 10B, and FIG. 11A and FIG. 11B illustrate a process (which can include photolithography steps) of forming the active devices masking layer on the Si layer 118 of the SOFTANOS substrate 110. In this step, because a certain amount of oxidation may have occurred on the surface of the Si layer 118 of the SOFTANOS substrate 110 prior to the beginning of the CMOS fabrication process, any silicon dioxide on the surface of the Si layer 118 is stripped away using, for example, a solution of hydrofluoric acid and deionized (DI) water. Then, a silicon dioxide layer 1010 that is, for example, about 11 nm thick is formed on the Si layer 118 of the SOFTANOS substrate 110. Then, a silicon nitride layer 1014 that is, for example, about 145 nm thick is formed on the silicon dioxide layer 1010. Then the silicon nitride layer 1014 is coated with a photoresist layer 1018, as shown in FIG. 10A and FIG. 10B.

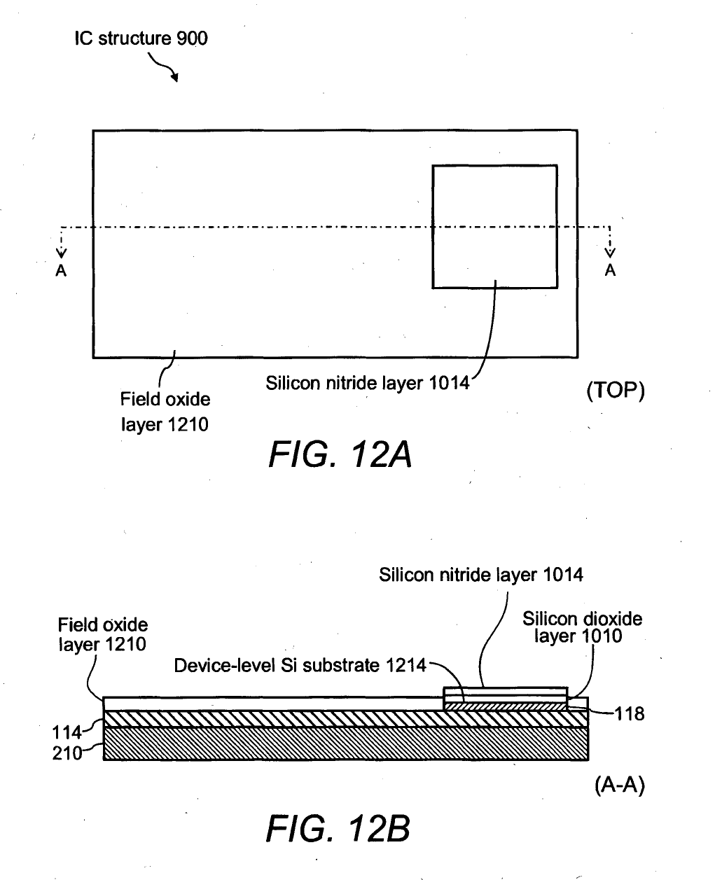

Referring now to FIG. 11A and FIG. 11B, a photolithography process, which is well known in the art, is performed to form a mask pattern 1110 in the photoresist layer 1018. That is, the photoresist layer 1018 is exposed to ultraviolet (UV) light through a photomask (not shown) that corresponds to the mask pattern 1110. Then the photoresist layer 1018 is developed, leaving the mask pattern 1110. The mask pattern 1110 is used to mask the Si layer 118 of the SOFTANOS substrate 110, which is used to define the features of the CMOS device 910 of the IC structure 900 of FIG. 9A and FIG. 9B. In one example, the CMOS device 910 to be formed may be a field effect transistor (FET). In this example, the mask pattern 1110 provides a rectangular island of the photoresist layer 1018, outside of which the Si layer 118 will be etched away, as described in FIG. 12A and FIG. 12B.

Referring to FIG. 12A and FIG. 12B, the IC structure 900 as shown in FIG. 11A and FIG. 11B undergoes an etching process, such as a plasma etching process, to etch away the silicon nitride layer 1014 and the silicon dioxide layer 1010 that is left exposed through the mask pattern 1110 shown in FIG. 11A and FIG. 11B. In doing so, a portion of the Si layer 118 is left exposed through the mask pattern 1110 of FIG. 11A and FIG. 11B. The exposed portion of the Si layer 118 is then oxidized (e.g., undergoes a wet oxidation process), which converts the exposed portion of the Si layer 118 to silicon dioxide, thereby forming a field oxide layer 1210. The process of converting silicon to silicon dioxide causes the thickness of the resulting field oxide layer 1210 to increase to about double that of the original Si layer 118 (e.g., to about 200 nm). Therefore, the resulting field oxide layer 1210 is etched back to a desired thickness of, for example, about 145 nm. This etching and oxidation step results in, for example, a device-level Si substrate 1214, which is still about 100 nm thick surrounded by the field oxide layer 1210 that is, for example, about 145 nm thick and formed on the AlN layer 114. One of the purposes of the field oxide layer 1210 is to protect the surface of the AlN layer 114 during subsequent CMOS fabrication process steps. Subsequent to the etching and oxidation step, the mask pattern 1110 (i.e., the photoresist island) is stripped away. Remaining atop the device-level Si substrate 1214 is the silicon dioxide layer 1010 and the silicon nitride layer 1014. The device-level Si substrate 1214 is the starting substrate for the CMOS device 910 of the IC structure 900 of FIG. 9A and FIG. 9B.

Various CMOS fabrication process steps disclosed herein that utilize a SOFTANOS substrate (e.g., the SOFTANOS substrate 110) may utilize the well-known photolithography process of photoresist coating, exposing, and developing, such as is described in FIG. 10A and FIG. 10B, FIG. 11A and FIG. 11B, and FIG. 12A and FIG. 12B. However, for the sake of simplicity, the well-known photolithography process that occurs during certain steps of the CMOS fabrication process described below may not be shown explicitly in the drawings, but is understood by those skilled in the art to have occurred.

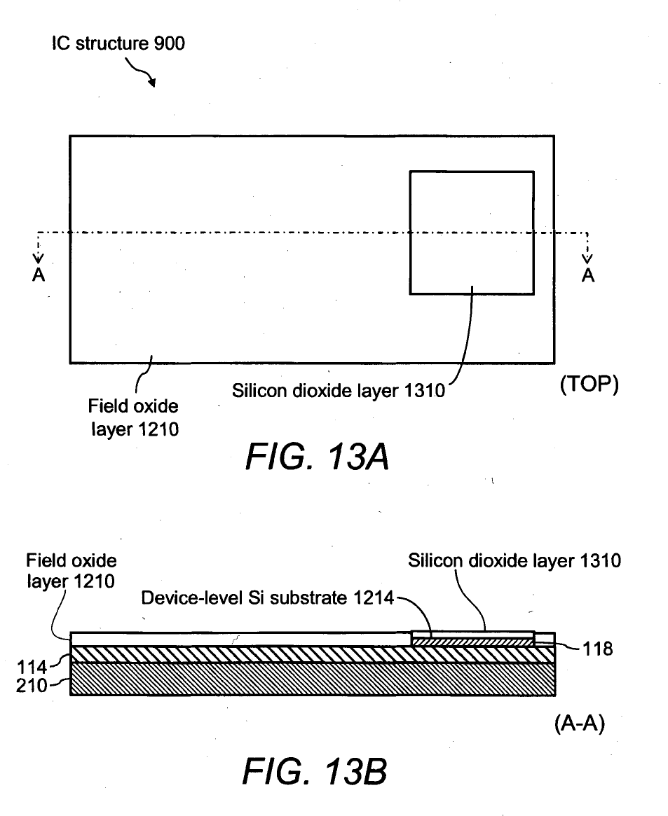

Referring to FIG. 13A and FIG. 13B, because a certain amount of contamination may be present, the silicon dioxide layer 1010 and the silicon nitride layer 1014 are stripped off of the device-level Si substrate 1214 by, for example, plasma etching. Then, a fresh layer of silicon dioxide is grown on the device-level Si substrate 1214. For example, a silicon dioxide layer 1310 is grown on the device-level Si substrate 1214.

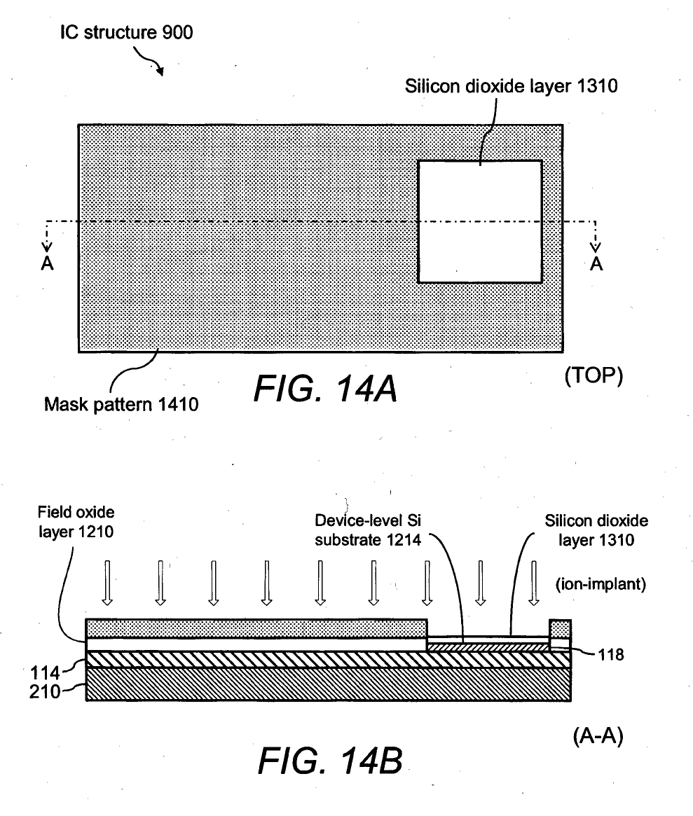

Referring to FIG. 14A and FIG. 14B, the IC structure 900 as shown in FIG. 13 undergoes a photolithography process to form a mask pattern 1410 in a layer of photoresist, after which an implant process is performed. In one example, if the CMOS device 910 is to be an n-type FET, then the mask pattern 1410 is used to perform an n-channel threshold implantation of the device-level Si substrate 1214. In this example, the mask pattern 1410 leaves the device-level Si substrate 1214 exposed. In the example of an n-type FET, p-type species (e.g., boron, i.e., BF₂) are implanted into the device-level Si substrate 1214 using known techniques to form an n-channel.

While the operations described with reference to FIG. 14A and FIG. 14B are exemplary for forming n-type active devices, such as n-type FETs, those skilled in the art will recognize that similar operations are performed to form p-type active devices, such as p-type FETs, but using n-type species (e.g., phosphorous) to perform the p-channel threshold implantation of the device-level Si substrate 1214.

Further, any number of implant processes may occur as needed according to FIG. 14A and FIG. 14B, such as regular n-channel transistor (RN) threshold implantation, regular p-channel transistor (PN) threshold implantation, low n-channel transistor (NL) threshold implantation, and low p-channel transistor (PL) threshold implantation.

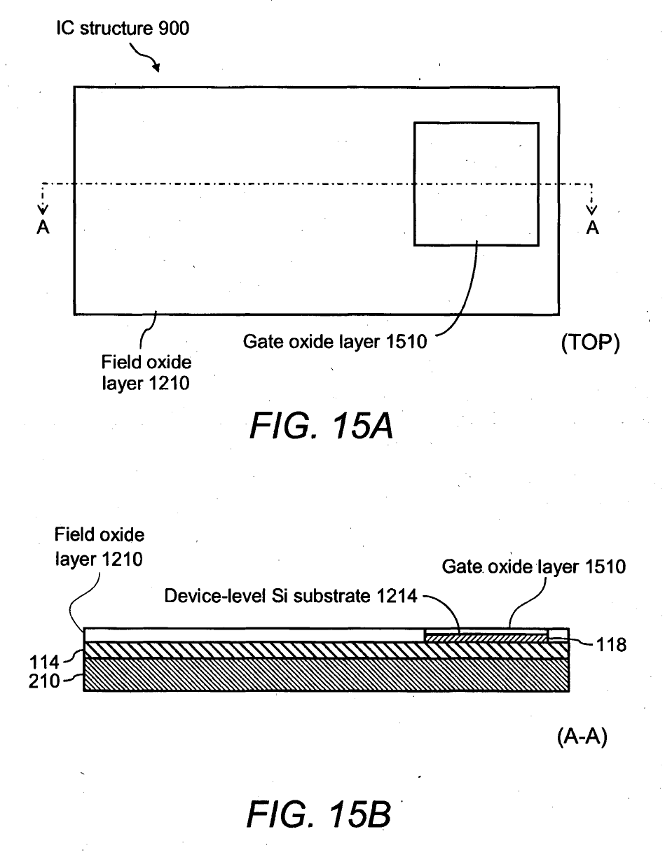

Referring to FIG. 15A and FIG. 15B, following the implant operation shown in FIG. 14A and FIG. 14B, the silicon dioxide layer 1310 is removed from the device-level Si substrate 1214 by, for example, etching with aqueous hydrofluoric acid. Then, a gate oxide layer 1510 that is, for example, about 8.2 nm thick (e.g., for a 0.25 μm transistor) is formed on the device-level Si substrate 1214.

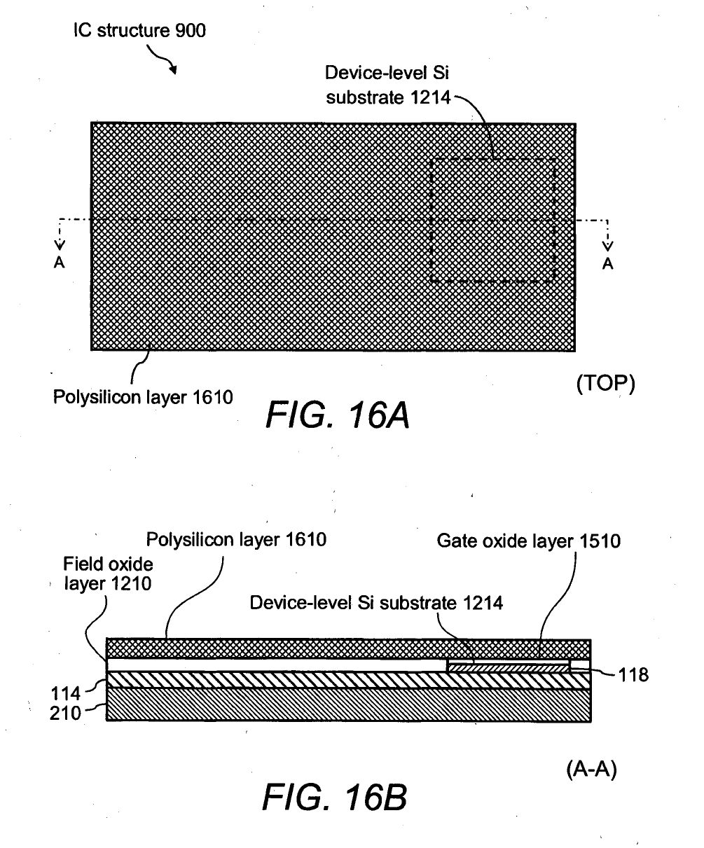

Referring to FIG. 16A and FIG. 16B, a blanket polysilicon layer 1610 that is, for example, about 250 nm thick is formed over substantially the entire surface of the IC structure 900. This is the first step of forming the polysilicon gate of the CMOS device 910.

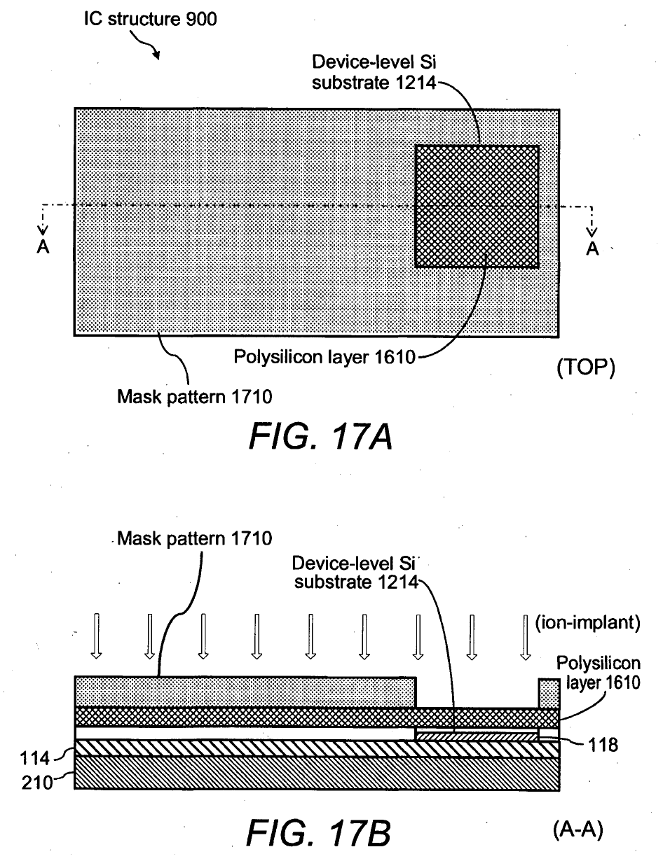

Referring to FIG. 17A and FIG. 17B, the IC structure 900 as shown in FIG. 16A and FIG. 16B undergoes a photolithography process to form a mask pattern 1710 in a layer of photoresist, after which an n+ poly implant process is performed to dope the CMOS device 910 (e.g., the gate of a FET). Because in this example the CMOS device 910 is to be an n-type FET, the mask pattern 1710 is used to perform an n+ implantation of the polysilicon layer 1610 at the location of the device-level Si substrate 1214. In this example, the mask pattern 1710 leaves the polysilicon layer 1610 exposed to implantation at the location of the device-level Si substrate 1214, and n+ species (e.g., phosphorous) are implanted into this portion of the polysilicon layer 1610 using known techniques, thereby forming the gate of the n-type FET.

While the n+ poly implant process described with reference to FIG. 17A and FIG. 17B is exemplary for forming n-type active devices, such as n-type FETs, those skilled in the art will recognize that a p+ poly implant process may be performed to form p-type active devices, such as p-type FETs, but using p+ species (e.g., boron) for doping the polysilicon layer 1610. Additionally, following any doping process, the dopants are activated by, for example, an annealing step.

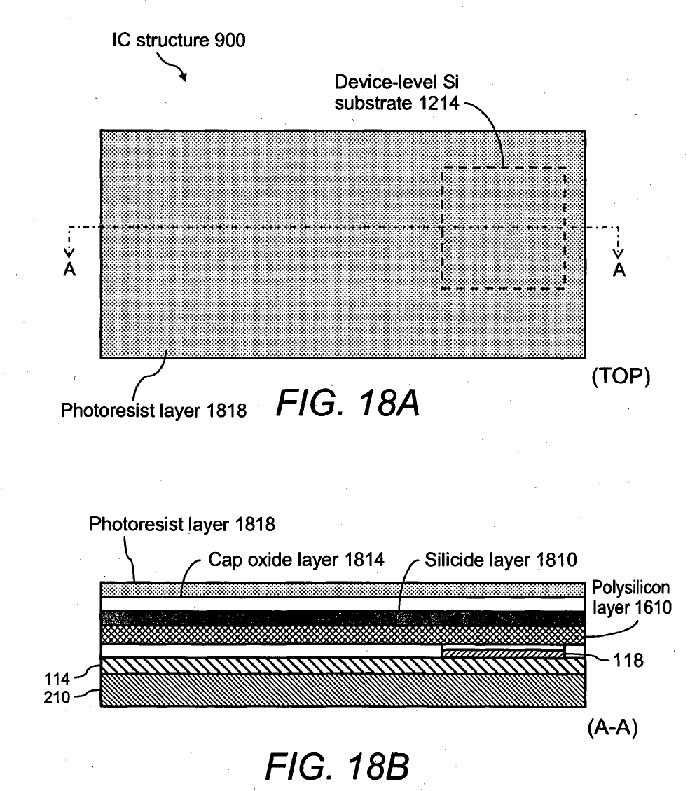

Referring to FIG. 18A and FIG. 18B, the mask pattern 1710 of FIG. 17A and FIG. 17B is stripped off of the polysilicon layer 1610 and a silicide blanket layer 1810 that is, for example cobalt silicide in one example or tungsten silicide in another example or nickel silicide in further example, about 150 nm thick is formed on the polysilicon layer 1610. The silicide layer 1810 is formed, for example, by sputtering. The silicide layer 1810 is an electrically conductive material that is added to reduce the electrical resistance of the polysilicon layer 1610. Then, the IC structure 900 is capped with, for example, a blanket layer of silicon dioxide that is formed, for example, by a plasma-enhanced chemical vapor deposition (PECVD) process. For example, a cap oxide layer 1814 that is about 170 nm thick is formed on the silicide layer 1810. Next, a photoresist layer 1818 is formed on the cap oxide layer 1814 in preparation for defining the gate features of the CMOS device 910 of the IC structure 900.

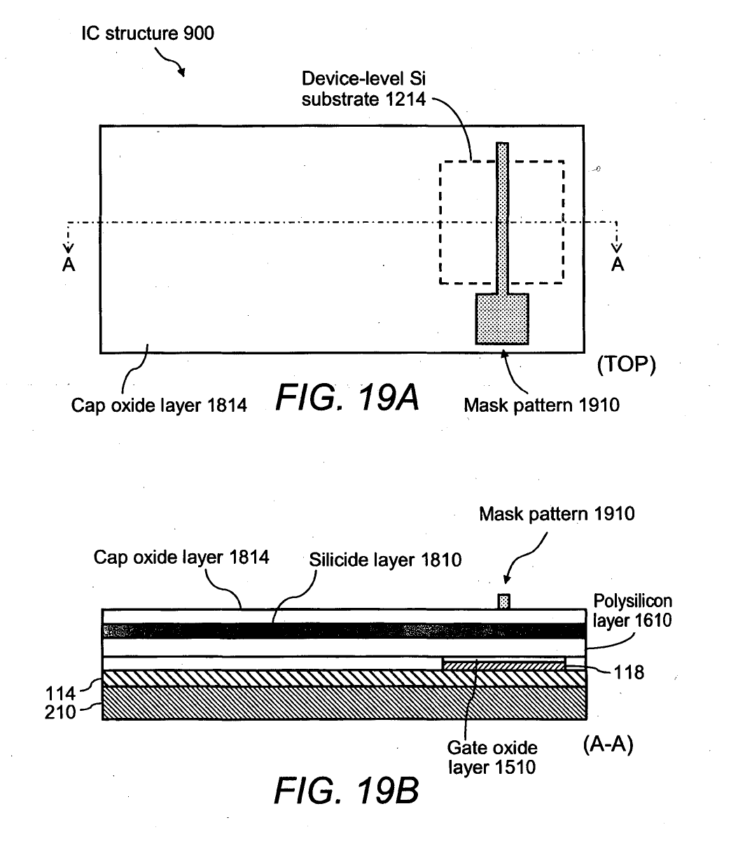

Referring to FIG. 19A and FIG. 19B, the IC structure 900 as shown in FIG. 18A and FIG. 18B undergoes a photolithography process to form a mask pattern 1910 in the photoresist layer 1818 of FIG. 18A and FIG. 18B.

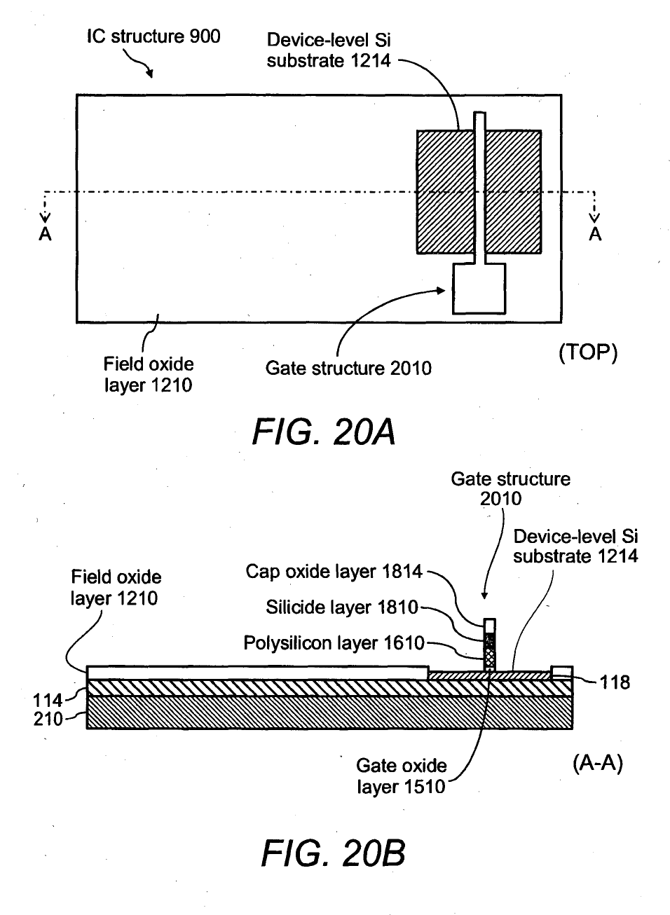

Referring now to FIG. 20A and FIG. 20B, the cap oxide layer 1814, the silicide layer 1810, the polysilicon layer 1610, and the gate oxide layer 1510 are etched, such as by plasma etching, according to the mask pattern 1910. In this way, a gate structure 2010 of the CMOS device 910 of the IC structure 900 is formed. More specifically, the portion of the cap oxide layer 1814, the silicide layer 1810, the polysilicon layer 1610, and the gate oxide layer 1510 that is exposed through the mask pattern 1910 is etched all the way to the field oxide layer 1210 and to the device-level Si substrate 1214, thereby forming the gate structure 2010 of the CMOS device 910 on the device-level Si substrate 1214.

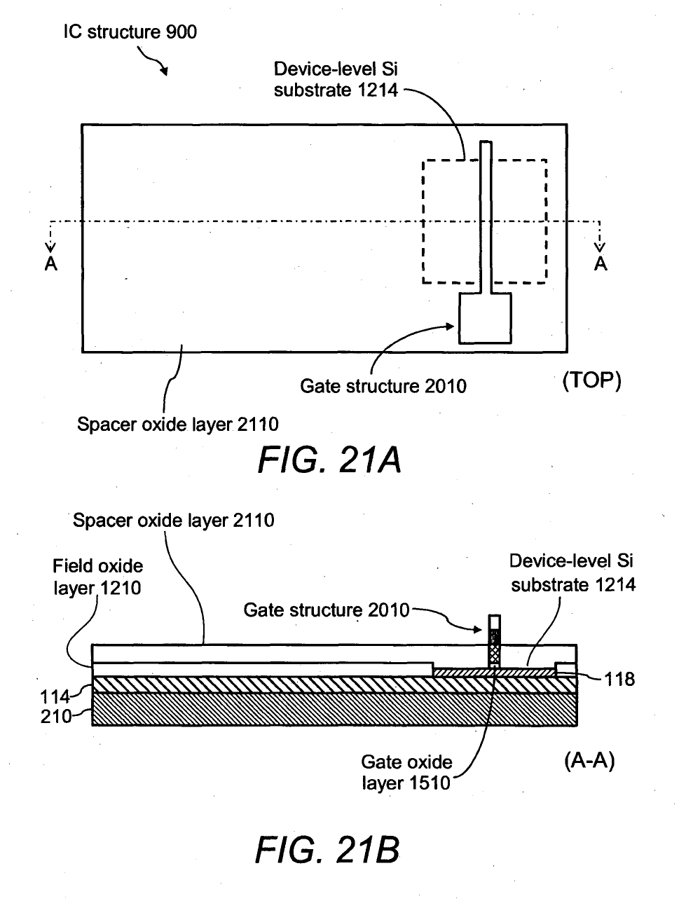

Referring to FIG. 21A and FIG. 21B, a blanket layer of silicon dioxide is formed over substantially the entire surface of the IC structure 900 of FIG. 20A and FIG. 20B in preparation for forming lightly doped drain (LDD) spacers at the gate structure 2010 of the CMOS device 910. For example, a spacer oxide layer 2110 that is about 200 nm thick is formed over substantially the entire surface of the IC structure 900, excluding over the gate structure 2010, as shown in FIG. 21A and FIG. 21B. The spacer oxide layer 2110 is formed, for example, using a PECVD process.

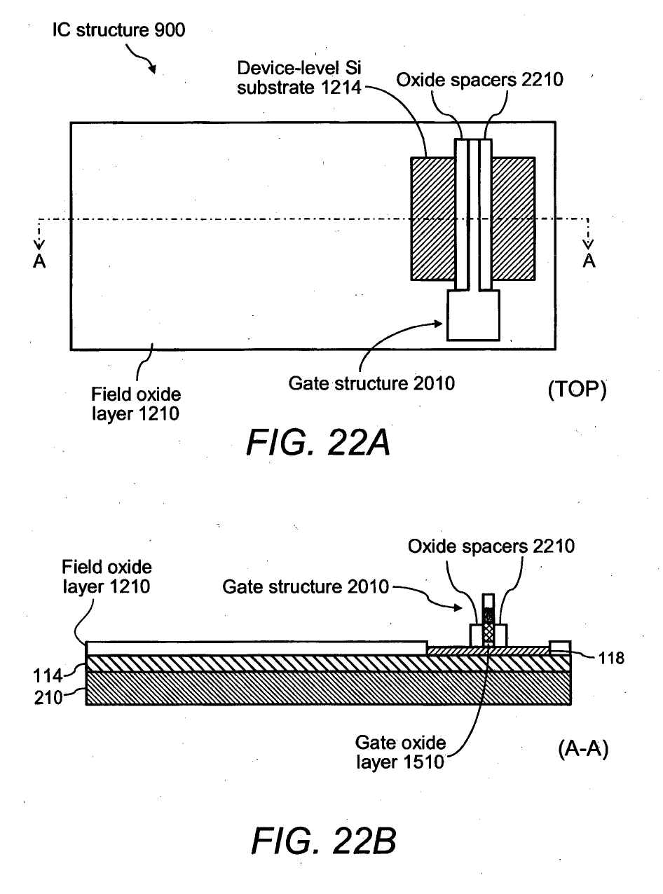

Referring to FIG. 22A and FIG. 22B, the IC structure 900 as shown in FIG. 21A and FIG. 22B undergoes a photolithography and etching process in which the spacer oxide layer 2110 is etched to form an oxide spacer 2210 on each side of the gate structure 2010 of the CMOS device 910. The width of each of the oxide spacers 2210 on each side of the gate structure 2010 may be, for example, about 0.14 μm. The purpose of the oxide spacers 2210 is to inhibit diffusion of the source and drain implant under the gate structure 2010 during any subsequent implant steps. Namely, when the n- and p-channel LDDs of the transistor are subjected to photolithography and implant steps, the oxide spacers 2210 function as a mask to prevent the species from impinging near the edges of the gate structure 2010.

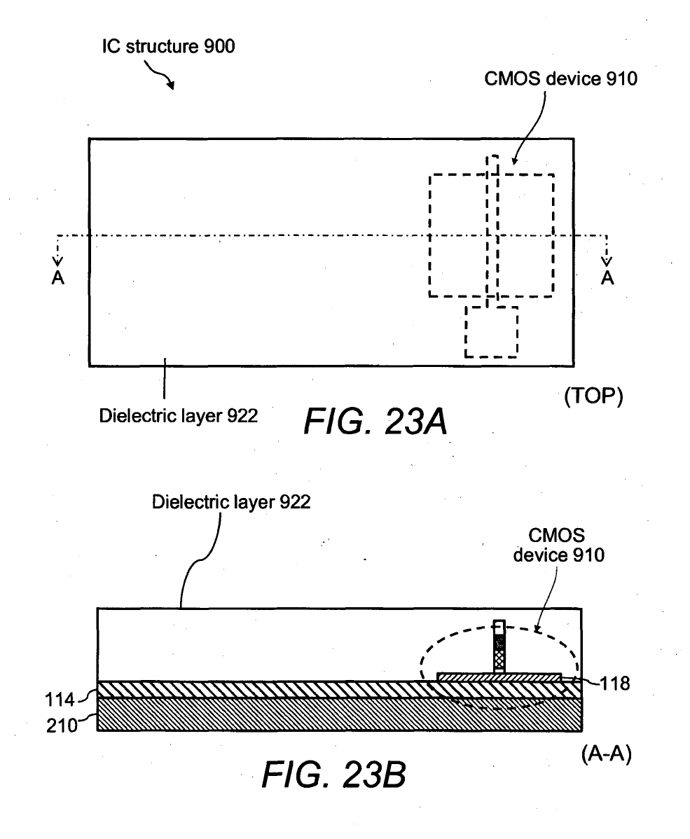

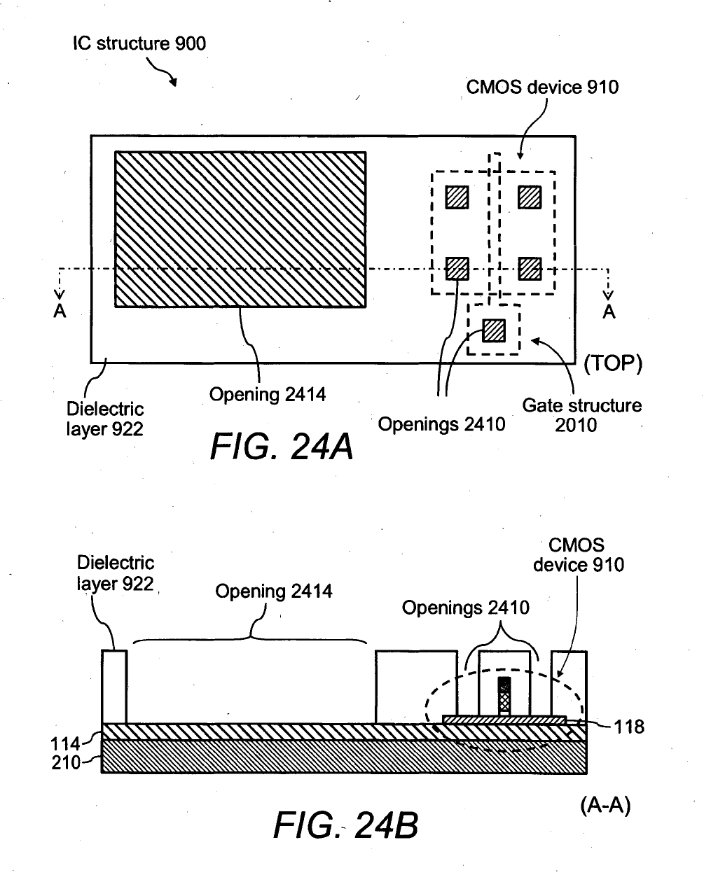

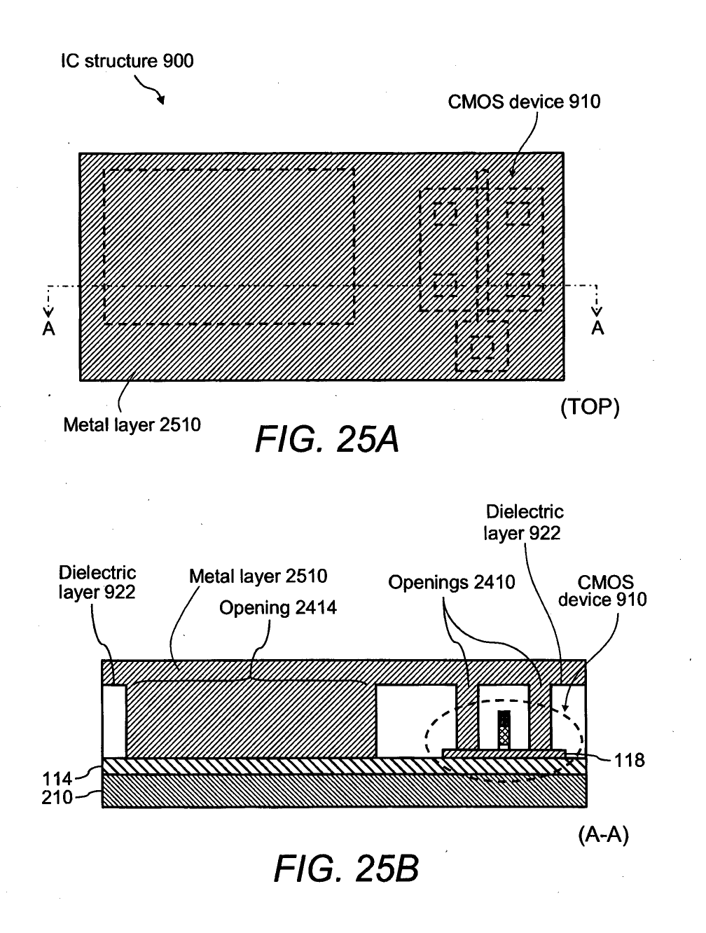

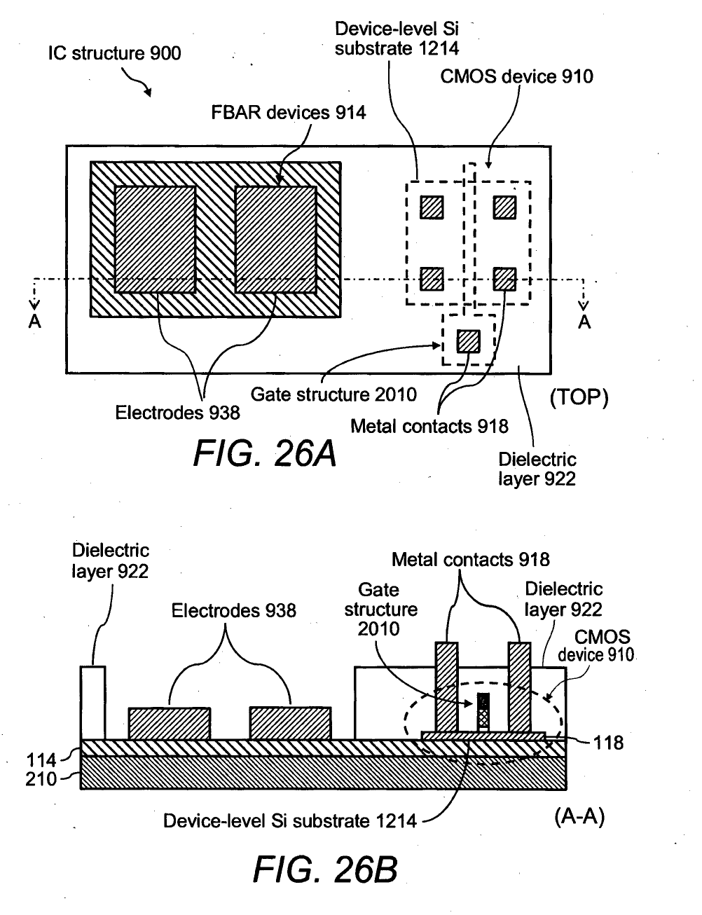

Referring to FIG. 23A and FIG. 23B, after completing the n- and p-channel LDD implant steps and any other implant steps, a blanket dielectric layer is formed over substantially the entire surface of the IC structure 900 of FIG. 22A and FIG. 22B. For example, the dielectric layer 922 is formed over the surface of the IC structure 900, as shown in FIG. 23A and FIG. 23B. In one example, the dielectric layer 922 is formed of BPSG ILD oxide and is about 1 μm thick. The dielectric layer 922 is formed, for example, using a PECVD process. The dielectric layer 922 may be formed as one single layer or by depositing multiple BPSG ILD oxide layers that total the desired thickness. The cap oxide layer 1814 of the gate structure 2010 (see FIG. 20A and FIG. 20B) as well as the oxide spacers 2210 become homogeneous with the dielectric layer 922. At the completion of this step, the CMOS device 910 is fully formed, excepting the metal contacts 918, which are the electrical contacts. FIG. 24A and FIG. 24B, FIG. 25A and FIG. 25B, and FIG. 26A and FIG. 26B describe the formation of the metal contacts 918 of the CMOS device 910 as well as the formation of the electrodes 938 of the FBAR devices 914.

Referring to FIG. 24A and FIG. 24B, the IC structure 900 as shown in FIG. 23A and FIG. 23B undergoes a photolithography and etching process in which the dielectric layer 922 is etched to provide openings 2410 that lead to certain portions of the device-level Si substrate 1214 and to certain portions of the gate structure 2010 of the CMOS device 910, as shown in FIG. 24A and FIG. 24B. Additionally, the dielectric layer 922 is etched to provide an opening 2414 that exposes the portion of the AlN layer 114 to be used for the FBAR devices 914.

Referring to FIG. 25A and FIG. 25B, a blanket layer 2510 of metal is deposited that for example is aluminum in one example or molybdenum in another example or any other high acoustic impedance metals or conductors in another example is formed over substantially the entire surface of the IC structure 900 of FIG. 24A and FIG. 24B and such that it fills the openings 2410 and the opening 2414 in the dielectric layer 922. For example, an aluminum layer 2510 that is, for example, about 1 μm thick is formed over the surface of the IC structure 900 and such that it fills the openings 2410 and the opening 2414, as shown in FIG. 25A and FIG. 25B. The aluminum layer 2510 is formed, for example, using a sputtering process in one example or evaporation process in another example. The aluminum layer 2510 may be formed as one single layer or by depositing multiple layers that total the desired thickness. By filling the openings 2410 with aluminum, an electrical path is provided through the dielectric layer 922 to the structures that form the CMOS device 910. For example, electrical paths are provided through the dielectric layer 922 to the source, drain, and gate of the CMOS device 910. By filling the opening 2414 with aluminum, metal suitable for forming the electrodes 938 of the FBAR devices 914 is provided through the dielectric layer 922 and all the way to the AlN layer 114.

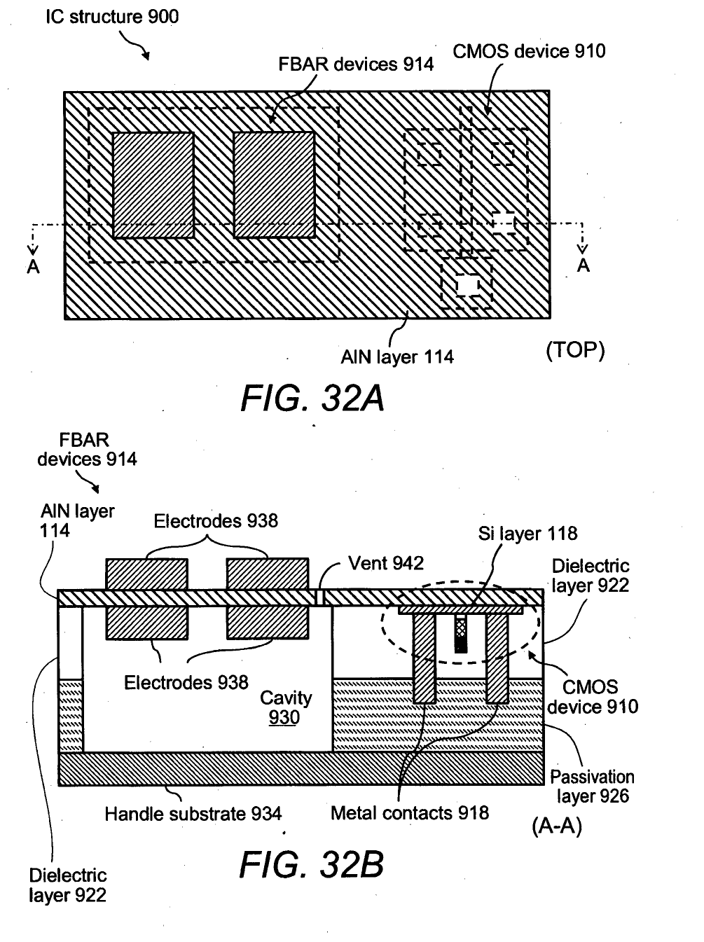

Referring to FIG. 26A and FIG. 26B, the IC structure 900 as shown in FIG. 25A and FIG. 25B undergoes a photolithography and etching process in which the aluminum layer 2510 for example is etched to define individual metal contacts 918 to the device-level Si substrate 1214 and to the gate structure 2010 of the CMOS device 910, as shown in FIG. 26A and FIG. 26B. For example, one metal contact 918 is provided at the gate of the CMOS device 910, two metal contacts 918 are provided at the source of the CMOS device 910, and two metal contacts 918 are provided at the drain of the CMOS device 910. Similarly, the aluminum layer 2510 is etched to define two of the four electrodes 938 that will form the two FBAR devices 914. One end of each of these two electrodes 938 is in contact with the AlN layer 114. The two electrodes 938 shown in FIG. 26A and FIG. 26B form half of the two FBAR devices 914, meaning one electrode 938 shown in FIG. 26A and FIG. 26B is the first electrode of the first FBAR device 914 and the other electrode 938 shown in FIG. 26A and FIG. 26B is the first electrode of the second FBAR device 914. The remaining two electrodes 938 will be formed in a later step (see FIG. 32A and FIG. 32B).

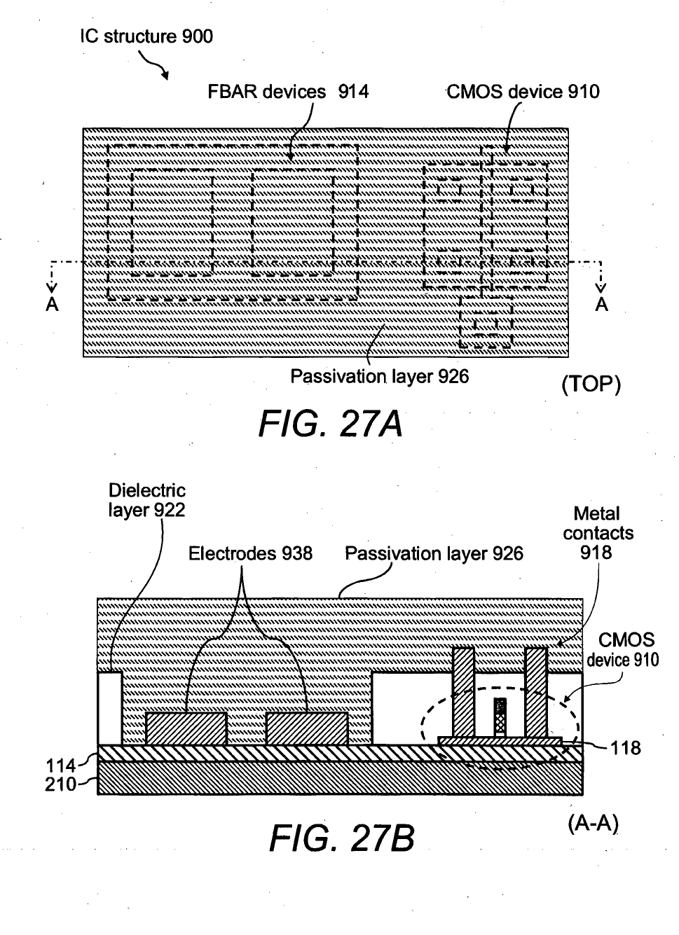

Referring to FIG. 27A and FIG. 27B, a blanket layer of passivation material is formed over substantially the entire surface of the IC structure 900 of FIG. 26A and FIG. 26B. For example, the passivation layer 926, which is, for example, about 1,200 nm thick, is formed over substantially the entire surface of the IC structure 900, as shown in FIG. 27A and FIG. 27B. In one example, the passivation layer 926 may be formed by a combination of two layers of material. For example, the passivation layer 926 may include a layer of phosphosilicate glass (PSG) that is, for example, about 500 nm thick and a layer of silicon nitride that is, for example, about 700 nm thick. The passivation layer 926 may be formed, for example, using a PECVD process. Electrical wiring between any CMOS devices is implemented under the passivation layer 926. At this stage of the process, the CMOS device fabrication is substantially complete.

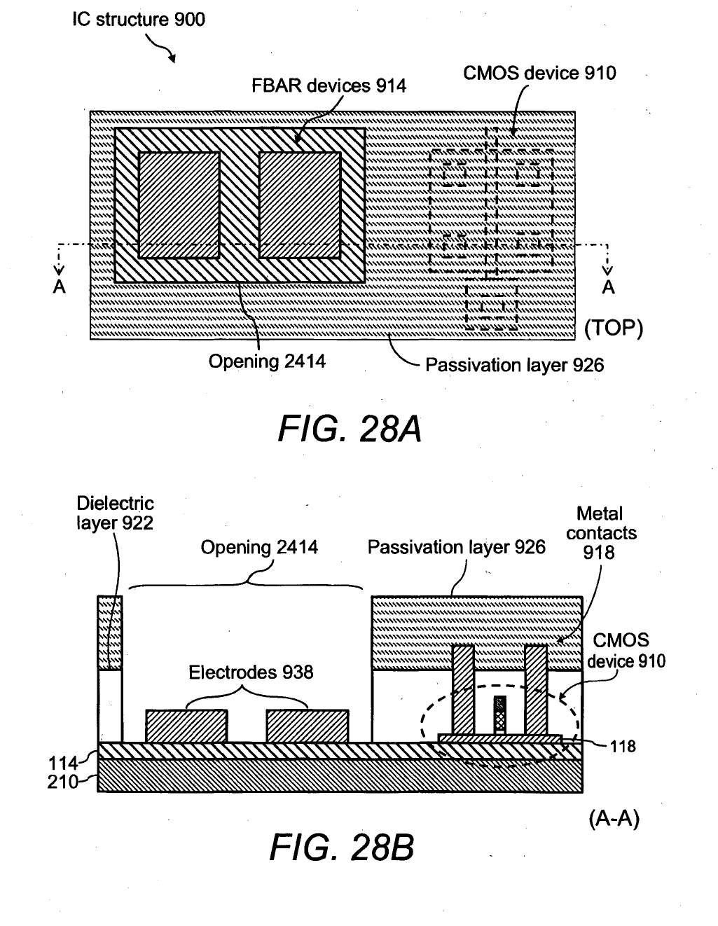

Referring to FIG. 28A and FIG. 28B, the IC structure 900 as shown in FIG. 27A and FIG. 27B undergoes a photolithography and etching process in which the passivation layer 926 is etched to reestablish the opening 2414 around the electrodes 938 of the FBAR devices 914 and, thereby, expose the electrodes 938. The electrodes 938 are in physical contact with the AlN layer 114, which has piezoelectric properties.

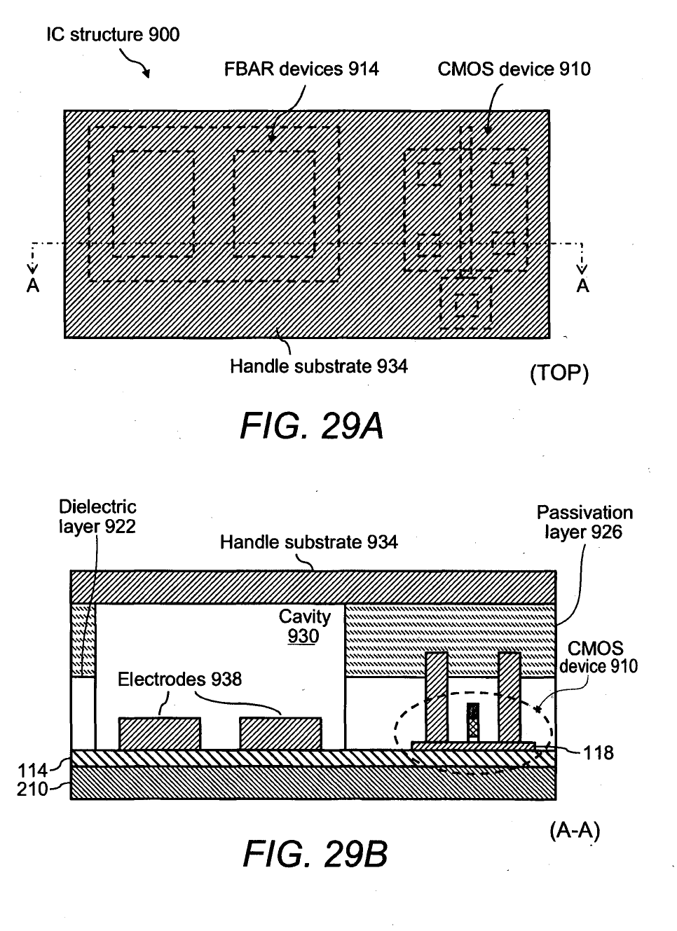

Referring to FIG. 29A and FIG. 29B, the passivation layer 926 is planarized by, for example, a CMP process or some other low temperature adhesive bond. Then, the handle substrate 934 is bonded to the passivation layer 926 by, for example, a fusion bonding process. In so doing, the cavity 930 is formed around the electrodes 938 of the FBAR devices 914. The total height of the cavity 930 is, for example, about 2.2 μm thick. In one example, the handle substrate 934 is about 600 μm thick.

Referring to FIG. 30A and FIG. 30B, the removable handle substrate 210 has been removed from the AlN layer 114. In one example, the removable handle substrate 210 is removed from the AlN layer 114 by being pried off with a knife-edge. This is possible due to the weak bond between the removable handle substrate 210 and the AlN layer 114 as described with reference to the step 318 of the method 300 in FIG. 3. In another example the removable handle substrate 210 is removed from the AlN layer 114 by undercutting the AlN/Silicon bond formed by silicon dioxide via fluorine plasma etch through etched holes in the removable handle wafer.

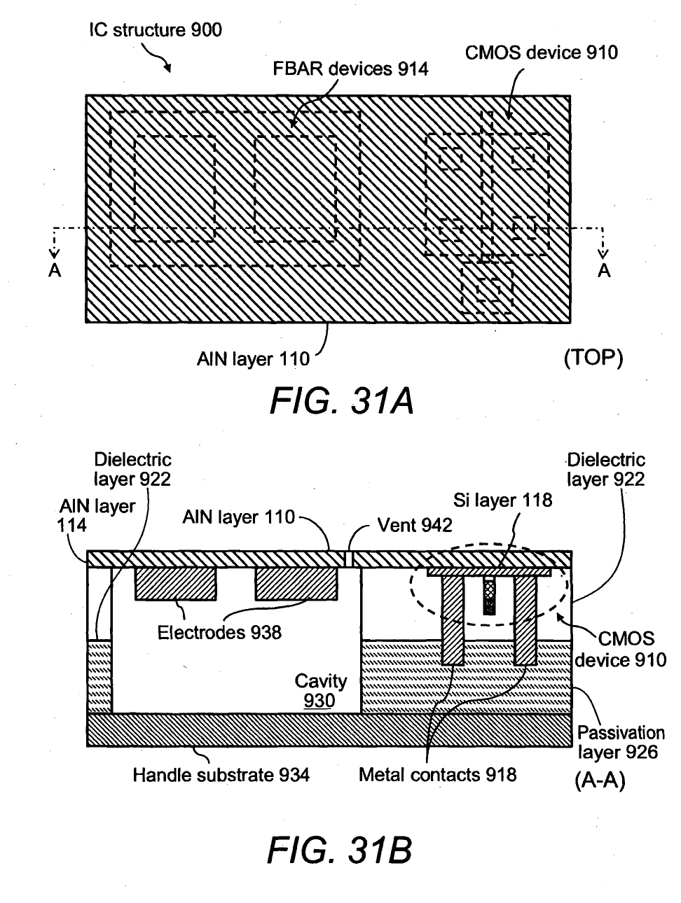

Referring to FIG. 31A and FIG. 31B, now using the handle substrate 934 as the base substrate, the IC structure 900 is inverted in preparation for forming the remaining two of the four electrodes 938 of the FBAR devices 914. Namely, the reverse side of the AlN layer 114 from the side that already has two electrodes 938 is exposed in preparation for forming the remaining two electrodes 938. In one example, at this stage of the process, the vent 942 is formed in the AlN layer 114 via an etching process. The vent 942 is an optional opening through the AlN layer 114 that allows air to enter the cavity 930 and thereby equalize the pressure on both sides of the AlN layer 114. Alternatively, the thin AlN layer 114 can be substantially mechanically and acoustically isolated from its surrounding structure by effectively a MEMS release which etches a pattern through the AlN layer 114 that isolates the FBAR device from the surrounding structure but leaving enough of the AlN layer 114 for mechanical support.

Referring to FIG. 32A and FIG. 32B, a blanket layer of metal (not shown) is formed over substantially the entire surface of the exposed AlN layer 114 that is for example aluminum, molybdenum or any other high acoustic impedance metal. The blanket layer of aluminum for example is formed, for example, using a sputtering process or another example by evaporation. Then, a photolithography process is used to form two more of the electrodes 938. The two electrodes 938 shown in FIG. 32A and FIG. 32B form the remaining half of the two FBAR devices 914, meaning one of the electrodes 938 shown in FIG. 32A and FIG. 32B is the second electrode of the first FBAR device 914 and the other of the electrodes 938 shown in FIG. 32A and FIG. 32B is the second electrode of the second FBAR device 914. The first electrodes 938 were formed previously, as described in FIG. 26A and FIG. 26B.

Once the two electrodes 938 shown in FIG. 32A and FIG. 32B are formed, the IC structure 900 is substantially completed. In one example, the thickness or height of each of the four electrodes 938 is about <1 μm. Due to the presence of the cavity 930, the electrodes 938 and the portion of the AlN layer 114 included in the FBAR devices 914 are fully exposed to the ambient atmosphere so that vibration of the FBAR devices 914 is not inhibited, thereby substantially achieving acoustic isolation from the surrounding medium.

Generally, the ground planes of the FBAR devices 914 are formed in the first metal layer of the CMOS fabrication process. The FBAR devices 914 are then formed on the AlN layer 114, and connections to the electrodes 938 and ground planes of the FBAR devices 914 are formed through the AlN layer 114 to the CMOS circuitry, such as to the CMOS device 910 and the like.

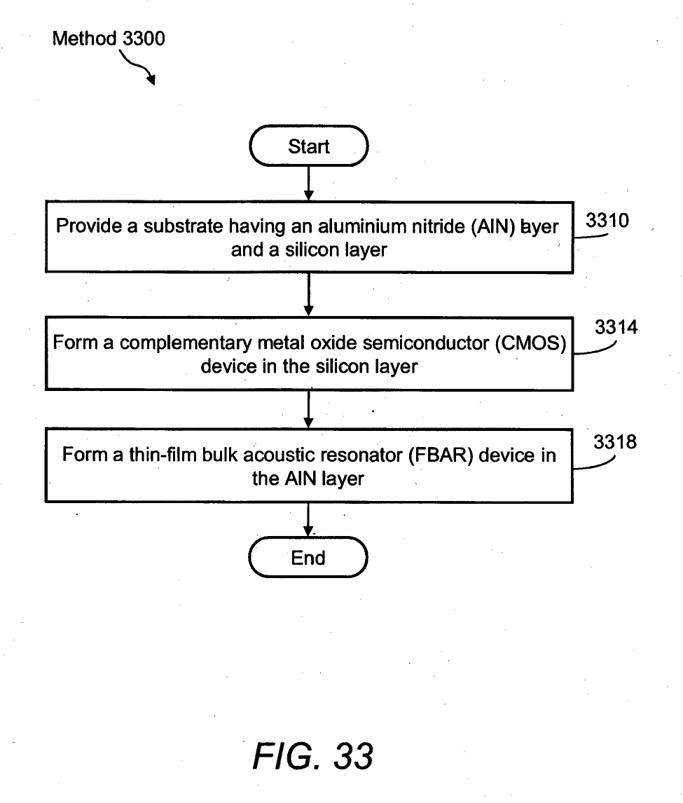

FIG. 33 is a flow diagram of an example of a method 3300 of integrating a CMOS device and an FBAR device using the SOFTANOS substrate 110, which is a low electrical conductivity, high thermal conductivity, and piezoelectric substrate. The method 3300 comprises the steps below.

At a step 3310, a SOFTANOS substrate, such as the SOFTANOS substrate 110 of FIG. 2, which is a low electrical conductivity, high thermal conductivity, and piezoelectric substrate, is provided as a starting substrate of any CMOS fabrication process of any CMOS manufacturer.

At a step 3314, a CMOS device is formed on a silicon layer of the SOFTANOS substrate. The CMOS device can comprise any suitable combination of integrated circuits and can include an arrangement of active or passive devices, or both. The CMOS device can be formed using any CMOS fabrication process of any CMOS manufacturer.

At step 3318, an FBAR device, such as the FBAR devices 914, is formed in the AlN layer 114 of the same SOFTANOS substrate and using the same CMOS fabrication process. FIG. 10A and FIG. 10B through FIG. 32A and FIG. 32B describe one example of forming both the CMOS device 910 (e.g., an n-type FET) and the FBAR devices 914 on the same SOFTANOS substrate 110.

As a result, a CMOS article (e.g., an integrated circuit) and at least one of the FBAR devices 914 formed on a SOFTANOS substrate, such as the SOFTANOS substrate 110 of FIG. 2, wherein the CMOS article provides high heat dissipation because of the SOFTANOS substrate, which is a high thermal conductivity SOI substrate that has piezoelectric properties. The CMOS article and the at least one FBAR device formed on the SOFTANOS substrate may include CMOS integrated circuits or devices that are higher power or have higher performance than is otherwise possible on conventional SOI substrates. This is because of the high heat dissipation that is possible through the AlN layer of the SOFTANOS substrate. Accordingly, the CMOS article (e.g., an integrated circuit) and the at least one FBAR device formed on the SOFTANOS substrate provide increased thermal management capability as compared with CMOS integrated circuits that are fabricated on conventional SOI substrates, which have poor thermal conductivity and poor piezoelectric properties.

Accordingly, the method 3300 is an example of a process of forming an FBAR device on a low electrical conductivity, high thermal conductivity, and piezoelectric substrate using a CMOS fabrication process, which reduces the complexity and cost of implementing both CMOS technology and FBAR technology as compared with using conventional substrates and methods. The mobile telephone is an example of an application that may benefit from the CMOS integrated circuit in combination with an FBAR device formed on a SOFTANOS substrate. In a conventional mobile telephone, one or more FBAR devices are typically installed, wherein each FBAR device is a discrete component that is manufactured and installed separately from other CMOS integrated circuit devices present in the mobile telephone. Having to implement discrete FBAR devices separate from the other CMOS integrated circuit devices adds significant cost and complexity to the mobile telephone manufacturing process. Additionally, the discrete FBAR devices consume valuable real estate within a mobile telephone. Using the method of integrating CMOS devices and FBAR devices on a single SOFTANOS substrate, the one or more FBAR devices may be integrated together with CMOS integrated circuit devices on a common SOFTANOS substrate in a mobile telephone, thereby significantly reducing cost, complexity, and size.

1. A method of forming an integrated circuit structure, the method comprising:
providing a substrate having an aluminium nitride (AIN) layer and a silicon layer, wherein the silicon layer covers at least a portion of the AIN layer;
forming a complementary metal oxide semiconductor (CMOS) device in the silicon layer; and
forming a thin-film bulk acoustic resonator (FBAR) device in the AIN layer, whereby the integrated circuit structure includes both the FBAR device and the CMOS device.

2. The method of claim 1, further comprising:
removing a part of the silicon layer to expose a portion the AIN layer;
wherein the FBAR device is formed in the exposed portion of the AIN layer.

3. The method of claim 1, wherein forming the FBAR device comprises:
positioning a first electrode on a first side of the AIN layer; and
positioning a second electrode on a second side of the AIN layer.

4. The method of claim 3, further comprising:
bonding a removable handle substrate to the AIN layer; and
removing at least one portion of the removable handle substrate to expose at least one portion of the AIN layer;
wherein positioning the first electrode is performed prior to removing the at least one portion of the removable handle substrate, and positioning the second electrode is performed subsequent to removing the at least one portion of the removable handle substrate.

5. The method of claim 4, wherein the removable handle substrate comprises a material selected from the following: silicon, a metal, and quartz.

6. The method of claim 3, wherein the first electrode is exposed to atmosphere.

7. The method of claim 3, further comprising:
providing a cavity adjacent to the second electrode, wherein the cavity is defined at least partly by the AIN layer.

8. The method of claim 7, further comprising:
providing an aperture in the AIN layer, the aperture providing a channel between the cavity and the atmosphere.

9. The method of claim 1, wherein the AIN layer is at least partially exposed to atmosphere at the FBAR device.

10. The method of claim 1, wherein a thickness of the AIN layer is between 50 nm and 1 μm.

11. The method of claim 1, wherein a thickness of the silicon layer is between 75 nm and HO nm.

12. The method of claim 1, wherein providing the substrate having the AIN layer and the silicon layer comprises:
forming the AIN layer on the silicon layer by molecular beam epitaxy (MBE), reactive sputtering, metal-organic chemical vapor deposition (MOCVD), or hydride vapor-phase epitaxy (HVPE).

13. [symbol] claim 1, wherein providing the substrate having the AIN layer and the silicon layer comprises:
forming the AIN layer on a bulk silicon layer;
implanting a gaseous hydrogen species into the bulk silicon layer, the implanted gaseous hydrogen species forming an implant boundary in the bulk silicon substrate; and
removing a portion of the bulk silicon layer at the implant boundary.

14. The method of claim 13, wherein removing the portion of the bulk silicon layer at the implant boundary comprises:
heat treating at least one portion of the bulk silicon layer to induce a fault plane at the implant boundary.

15. The method of claim 14, wherein heat treating the at least one portion of the bulk silicon layer includes heating the bulk silicon layer to a temperature of between 400 degrees C. and 600 degrees C.

16. The method of claim 13, further comprising:
heating at least one part of the integrated circuit structure to a temperature of about 1,100 degrees C. for about 1 hour, whereby residual damage to the silicon layer caused by implanted hydrogen is annealed, and whereby hydrogen is removed from the silicon layer.

17. An integrated circuit structure, comprising:
an aluminum nitride (AIN) layer;
a silicon layer that covers a portion of the AIN layer;
one or more CMOS devices formed in the silicon layer; and
one or more thin-film bulk acoustic resonators (FBARs) formed in the AIN layer.

18. The integrated circuit structure of claim 17, wherein the FBAR device includes a first electrode on a first side of the AIN layer and a second electrode on the second side of the AIN layer.

19. The integrated circuit structure of claim 17, wherein the first electrode is exposed to atmosphere.

20. The integrated circuit structure of claim 19, further comprising:
a cavity adjacent to the second electrode, wherein the cavity is defined at least partly by the AIN layer.
